(19) United States
(12) Patent Application Publication
(10) Pub. No.: US 2025/0265386 A1
(43) Pub. Date: Aug. 21, 2025

(54) SYSTEMS AND METHODS FOR DROUGHT PROJECTION

(71) Applicant: CDM Smith Inc., Boston, MA (US)

(72) Inventors: Kirk S. Westphal, Stow, MA (US); Mark Maimone, Huntington Station, NY (US); Timothy B. Adams, Chicopee, MA (US); Sebastian Malter, Philadelphia, PA (US); Amara Regehr, Somerville, MA (US); Joshua J. Soper, Jamaica Plain, MA (US)

(21) Appl. No.: 19/054,655

(22) Filed: Feb. 14, 2025

Related U.S. Application Data
(60) Provisional application No. 63/554,792, filed on Feb. 16, 2024.

(51) Int. Cl. G06F 30/20

(52) U.S. Cl. CPC G06F 30/20

(57) ABSTRACT

Embodiments provide drought projection for real-world geographic areas. One such embodiment identifies at least one climate model associated with a real-world geographic area. An evaluation is performed to determine whether the identified at least one climate model is valid for direct drought projection for the real-world geographic area. Based on a result of the evaluating, a drought projection technique is selected and the drought projection technique selected is employed to generate at least one drought projection for the real-world geographic area. The at least one drought projection includes an indication of projected drought frequency, projected drought duration, and projected drought intensity.

### RELATED APPLICATION

This application claims the benefit of U.S. Provisional Application No. 63/554,792, filed on Feb. 16, 2024. The entire teachings of the above application are incorporated herein by reference.

### BACKGROUND

Historically, for drought projection, water managers in the U.S. have looked backwards to historical records. In most U.S. states, the reliability of a water supply system, either surface water or groundwater or combined, has been characterized by its ability to withstand and recover from a recurrence of the most severe drought on record while providing desired amounts of water. This leaves no room for future droughts that may be more intense, more frequent, and/or longer in duration.

### SUMMARY

For decades, hydrologic conditions resulting from extreme rainfall events have been well-categorized and understood in terms of identifiable and universal flood statistics: statistical return frequencies for various combinations of rainfall intensity and duration and resulting flood stage derived through deterministic modeling. These values guided the design of infrastructure and facilities, property insurance programs, and both watershed and city planning. Recently, as changing trends in the key climate variables of precipitation and air temperature have emerged and accelerated, the state of the science in climate change-induced flood risk has applied itself to re-characterizing return periods, event-based precipitation patterns, and flood depths by utilizing available predictive data to understand future flood probabilities and impacts.

Unlike floods, droughts are not characterized by universal or practical statistics that lend themselves to reliability assessments or permitting/allocation. Floods are considered to be individual “hydrologic events” and can be characterized by accepted and practical statistics, but droughts are inherently more dynamic. Droughts can last for three months or twenty years, and can be marked by both sudden and severe precipitation deficits, or gradual and prolonged deficits. Droughts can also occur in the form of consecutive within-year droughts, in which the return frequency is not only a benchmark but can become an inherent part of the problem if supply systems do not naturally replenish the water from one year to the next. Research on climate impacts to future droughts has been largely centered on projected trends, historical hindcasting, and composite condition indices, all of which are useful but generally much more qualitative than flood forecasts. This makes the risks and adverse impacts of droughts more difficult to predict and quantify.

The methodologies of embodiments described herein present example novel methods to utilize data, e.g., publicly available rain gage data, and publicly available downscaled climate data, from climate model(s), e.g., General Circulation Model(s) (GCM(s)), to project or predict frequency, duration, and intensity of future rainfall deficits, which may be long-term (e.g., multi-year)—a primary cause of regional droughts across the U.S. and elsewhere. While embodiments can use generally accepted climate projections in accordance with Phase 5 of the Coupled Model Intercomparison Project (CMIP5) and associated future emissions scenarios as severe as Representative Concentration Pathway 8.5 (RCP8.5), in which efforts to constrain greenhouse gas emissions are not assumed until late in the 21^{st} century, embodiments can also be used with other variations on climate forecasts and emissions scenarios (e.g., CMIP6, etc.).

While GCMs are recognized for their ability to project the probability of monthly rainfall in a given future time period, GCMs are generally not calibrated to reproduce the long-term cumulative rainfall deficits, defined herein as including net sum over n consecutive months of differences between projected rainfall for month n and the corresponding long-term average rainfall for its associated month (January, February, etc.). Embodiments can evaluate cumulative rainfall deficits of, e.g., up to five years (n=60 months) and provide new and innovative example methods of analyzing long-term GCM performance before applying GCM(s) for drought simulation and forecasting. In addition, an embodiment provides a method that combines stochastic analysis of historical rainfall patterns with trends from local GCMs to project year-over-year cumulative rainfall deficits resulting from climate change for the real-world geographic area.

An example embodiment is directed to a computer-implemented method for drought projection for a real-world geographic area. The method begins by identifying at least one climate model associated with the real-world geographic area. Next, the method evaluates whether the identified at least one climate model is valid for direct drought projection for the real-world geographic area. Then, based on a result of the evaluating, a drought projection technique is selected and the drought projection technique selected is employed to generate at least one drought projection for the real-world geographic area. The at least one drought projection includes an indication of projected drought frequency, projected drought duration, and projected drought intensity. According to one such embodiment, the at least one climate model may include downscaled daily precipitation data from at least one of a GCM included in a Coupled Model Intercomparison Project (CMIP) model simulation, an RCP emission scenario, and an ensemble of multiple climate models.

In an example embodiment, the evaluating may include: (1) using the identified at least one climate model, generating a rainfall hindcast for the real-world geographic area; (2) determining a difference between the generated rainfall hindcast and historical rainfall data for the real-world geographic area; and (3) based on the determined difference, determining a level of validity of the at least one climate model for direct drought projection for the real-world geographic area, wherein the determined level of validity is the result of the evaluating. According to one such embodiment, the generated rainfall hindcast may include at least one rainfall average for the real-world geographic area. The determining the difference may include determining a variance between the at least one rainfall average and the historical rainfall data. The variance may be the determined difference. In another such embodiment, the generated rainfall hindcast may include at least one cumulative rainfall deficit for the real-world geographic area. The determining the difference may include determining a variance between (i) an expected value of the at least one cumulative rainfall deficit and (ii) the historical rainfall data. The variance may be the determined difference. In yet another such embodiment, the generated rainfall hindcast may include at least one cumulative rainfall deficit for the real-world geographic area and determining the difference may include determining a variance between at least one of a frequency and an intensity of the at least one cumulative rainfall deficit and the historical rainfall data. The variance may be the determined difference. In one such embodiment, the generated rainfall hindcast may include at least one cumulative rainfall deficit for the real-world geographic area. The determining the difference may include determining a variance between at least one percentile of the at least one cumulative rainfall deficit and the historical rainfall data. The variance may be the determined difference. According to another such embodiment, the generated rainfall hindcast may be a stochastic rainfall hindcast and the historical rainfall data may be stochastically-generated historical rainfall data.

According to another example embodiment, based on the result of the evaluating, selecting the drought projection technique and employing the drought projection technique selected to generate the at least one drought projection for the real-world geographic area may include, responsive to the result of the evaluating indicating that the identified at least one climate model is valid for direct drought projection: (1) selecting a direct drought projection technique that utilizes the identified at least one climate model and (2) generating the at least one drought projection using the selected direct drought projection technique.

In an example embodiment, based on the result of the evaluating, selecting the drought projection technique and employing the drought projection technique selected to generate the at least one drought projection for the real-world geographic area may include, responsive to the result of the evaluating indicating that the identified at least one climate model is valid for direct drought projection: (1) selecting a direct stochastic drought projection technique that utilizes the identified at least one climate model and (2) stochastically generating the at least one drought projection using the selected direct stochastic drought projection technique.

According to another example embodiment, based on the result of the evaluating, selecting the drought projection technique and employing the drought projection technique selected to generate the at least one drought projection for the real-world geographic area may include, responsive to the result of the evaluating indicating that the identified at least one climate model is not valid for direct drought projection: (1) selecting a delta change factor (DCF)-based drought projection technique that utilizes the identified at least one climate model; (2) processing historical rainfall data for the real-world geographic area using the selected DCF-based drought projection technique to generate adjusted rainfall data for the real-world geographic area; and (3) using the adjusted rainfall data, stochastically generating the at least one drought projection. In one such embodiment, the selected DCF-based drought projection technique may be a modified Hybrid-Delta technique. Processing the historical rainfall data using the selected DCF-based drought projection technique to generate the adjusted rainfall data may include: (1) processing the historical rainfall data using the identified at least one climate model to generate a plurality of projected rainfall values; (2) identifying a subset of the plurality of projected rainfall values, the subset having projected rainfall values greater than zero; (3) calculating at least one integer DCF corresponding to a respective at least one integer percentile of the projected rainfall values of the subset; and (4) applying the calculated at least one integer DCF to a corresponding at least one integer percentile of historical rainfall values of the historical rainfall data. Applying the calculated at least one integer DCF may produce the adjusted rainfall data. According to another such embodiment, the selected DCF-based drought projection technique may be a ranking DCF technique. Processing the historical rainfall data using the selected DCF-based drought projection technique to generate the adjusted rainfall data may include: (1) processing the historical rainfall data using the identified at least one climate model to generate a plurality of projected rainfall values; (2) identifying a first subset of the plurality of projected rainfall values, the first subset corresponding to a time period associated with the at least one drought projection; (3) identifying a second subset of the plurality of projected rainfall values, the second subset corresponding to a time period associated with the historical rainfall data; and (4) applying at least one DCF to a corresponding at least one historical rainfall value of the historical rainfall data. A rank of a given historical rainfall value of the historical rainfall data may correspond to at least one of: (i) a respective rank of a projected rainfall value of the first subset and (ii) a respective rank of a projected rainfall value of the second subset. Applying the at least one DCF may produce the adjusted rainfall data. Further, in yet another such embodiment, the selected DCF-based drought projection technique may be a Hybrid-Delta technique.

In an example embodiment, based on the result of the evaluating, selecting the drought projection technique and employing the drought projection technique selected to generate the at least one drought projection for the real-world geographic area may include, responsive to the result of the evaluating indicating that the identified at least one climate model is not valid for direct drought projection: (1) selecting a stochastic DCF-based drought projection technique that utilizes the identified at least one climate model; (2) processing historical rainfall data for the real-world geographic area to generate stochastic historical rainfall data for the real-world geographic area; (3) processing the stochastic historical rainfall data using the selected stochastic DCF-based drought projection technique to generate stochastic adjusted rainfall data for the real-world geographic area; and (4) using the stochastic adjusted rainfall data, stochastically generating the at least one drought projection.

According to another example embodiment, the evaluating may include, using the identified at least one climate model, generating a rainfall hindcast for the real-world geographic area and using the generated rainfall hindcast to calculate at least one of cumulative precipitation, a cumulative precipitation deficit, and at least one cumulative precipitation deficit statistic. In one such embodiment, using the generated rainfall hindcast to calculate the at least one cumulative precipitation deficit statistic may include: (1) based on the generated rainfall hindcast, defining a set of a precipitation timeseries sequences; (2) calculating respective cumulative precipitation deficits corresponding to the precipitation timeseries sequences; and (3) based on a size of the defined set and the respective cumulative precipitation deficits calculated, calculating at least one cumulative precipitation deficit frequency (or likelihood). The calculated at least one cumulative precipitation deficit frequency may be the at least one cumulative precipitation deficit statistic. According to another such embodiment, the defining may include performing at least one of: (i) based on a duration value, filtering the generated rainfall hindcast and (ii) stochastically sampling the generated rainfall hindcast. A result of the performing may be the defined set of the precipitation timeseries sequences. In another embodiment, the generated rainfall hindcast may be a stochastic rainfall hindcast for the real-world geographic area. The evaluating may further include, based on the cumulative precipitation deficit, calculating at least one of a drought return interval and a drought annual exceedance probability (AEP).

In an example embodiment, the method may further include, based on the generated at least one drought projection, simulating at least one scenario of a real-world water system using at least one of a water resource model, a groundwater model, a water supply model, and a hydrologic model. According to one such embodiment, the real-world water system may include at least one of a reservoir, an aquifer, a river, a stream, a lake, a pond, a wetland, a marsh, a bog, a swamp, an estuary, a spring, a bay, a lagoon, a delta, and a canal.

Another example embodiment is directed to a computer-based system for drought projection for a real-world geographic area. The system includes at least one processor and a memory with computer code instructions stored thereon. The at least one processor and the memory, with the computer code instructions, are configured to cause the system to implement any embodiments or combination of embodiments described herein.

Yet another embodiment is directed to a computer program product for drought projection for a real-world geographic area. The computer program product includes a non-transitory computer-readable medium with computer code instructions stored thereon. The computer code instructions are configured, when executed by at least one processor, to cause an apparatus associated with the at least one processor to implement any embodiments or combination of embodiments described herein.

It is noted that embodiments of the method, system, and computer program product may be configured to implement any embodiments or combination of the embodiments described herein.

### BRIEF DESCRIPTION OF THE DRAWINGS

The foregoing will be apparent from the following more particular description of example embodiments, as illustrated in the accompanying drawings in which like reference characters refer to the same parts throughout the different views. The drawings are not necessarily to scale, emphasis instead being placed upon illustrating embodiments.

FIG. 1A is an example matrix of historic rainfall deficits for a 60-month time range according to an embodiment.

FIG. 1B is an example matrix of simulated historic rainfall deficits for the 60-month time range of FIG. 1A.

FIG. 2 is an example graph of expected values of cumulative rainfall deficits over 24 months according to an embodiment.

FIG. 3 is an example comparison of rain gage and GCM rainfall deficit percentiles according to an embodiment.

FIG. 4 illustrates example timeseries of cumulative rainfall surplus and deficit over 60 months comparing rain gage and GCM according to an embodiment.

FIG. 5 is an example graph of expected values of cumulative rainfall deficits showing current gage values and end of century GCM values for two emission scenarios according to another embodiment.

FIG. 6 is an example comparison of current and projected rainfall deficit percentiles for two emission scenarios according to an embodiment.

FIG. 7A is an example matrix of climate model simulated historic rainfall deficits according to an embodiment.

FIG. 7B is an example matrix of projected future rainfall deficits by the climate model(s) of FIG. 7A.

FIG. 8 is an example framework for climate-induced rainfall deficit projections according to an embodiment.

FIG. 9 is an example graph comparing current expected rainfall deficits calculated from a rain gage with results from climate models according to an embodiment.

FIG. 10 is an example graph comparing direct climate model projection results with projection results from DCFs according to an embodiment.

FIG. 11 is an example graph of cumulative rainfall deficits and surpluses from example rain gages according to an embodiment.

FIG. 12 illustrates example grid cells according to an embodiment.

FIG. 13 is an example scatter plot of monthly rainfall data for analyzing independence of monthly deficits according to an embodiment.

FIG. 14 is an example table of monthly rainfall totals according to an embodiment.

FIG. 15 is an example table of stochastically sequenced years by months according to an embodiment.

FIG. 16 is an example table of stochastically sequenced historical monthly rainfall values for a two-year sequence according to an embodiment.

FIG. 17 is an example table of stochastically generated cumulative rainfall gage values for a two-year sequence according to an embodiment.

FIG. 18 is an example table of stochastically generated cumulative rainfall deficits and surpluses for a two-year sequence according to an embodiment.

FIG. 19 is an example comparison of average observed monthly rainfall and climate model rainfall hindcasts according to an embodiment.

FIG. 20 is an example comparison of average observed rainfall and climate model rainfall hindcasts according to another embodiment.

FIG. 21 is an example comparison of average observed rainfall and climate model rainfall hindcasts according to yet another embodiment.

FIG. 22 illustrates a comparison of GCM and rain gage 24-month timeseries of cumulative rainfall surplus and deficit by percentiles according to an embodiment.

FIG. 23 illustrates a comparison of GCM and rain gage 24-month timeseries of cumulative rainfall surplus and deficit by percentiles according to another embodiment.

FIG. 24 illustrates a comparison of GCM and rain gage 24-month timeseries of cumulative rainfall surplus and deficit by percentiles according to yet another embodiment.

FIG. 25A is an example matrix of historic rainfall deficits from a rain gage for a 60-month time range according to another embodiment.

FIG. 25B is an example matrix of simulated historic rainfall deficits from GCMs for the time range of FIG. 25A.

FIG. 26A is an example matrix of historic rainfall deficits for a time range according to yet another embodiment.

FIG. 26B is an example matrix of simulated historic rainfall deficits for the time range of FIG. 26A.

FIG. 27 is an example plot of a comparison of rain gage and GCM simulated expected rainfall deficit values with 10% uncertainty range shading according to an embodiment.

FIG. 28 is an example plot of a comparison of rain gage and GCM simulated expected rainfall deficit values with 10% uncertainty range shading according to another embodiment.

FIG. 29 is an example comparison plot of cumulative rainfall surplus/deficit percentiles from a rain gage and GCMs according to an embodiment.

FIG. 30 is an example comparison plot of rainfall surplus/deficit frequency values from a rain gage and GCMs according to an embodiment.

FIG. 31 is an example plot of rainfall deficit return intervals from a rain gage and GCM simulated hindcast and projected values according to an embodiment.

FIG. 32 is a flowchart of a method for drought projection for a real-world geographic area according to an example embodiment.

FIG. 33 is a flowchart of an example decision process for drought projection technique selection according to an example embodiment.

FIG. 34 is a block diagram of an example embodiment of an internal structure of a computer in which various embodiments of the present disclosure may be implemented.

### DETAILED DESCRIPTION

A detailed description of example embodiments follows.

Embodiments provide major advancements in drought projection. One example advancement of embodiments is replacing the conventional practice of “blindly” projecting future drought statistics with GCMs that may only be calibrated to individual monthly rainfall probabilities, with a new example technique of assessing “drought efficacy” of GCMs, alone or in ensembles, using new example analysis methods and/or newly developed graphical evaluations of long-term rainfall deficits before employing the GCMs for future quantitative drought characterization/prediction. Aspects of example analysis methods are described below. Further, it is noted that the example results described hereinbelow are from an analysis of Marengo, Illinois for illustrative purposes only.

Another example advancement of embodiments is simplification of variables. Most existing drought research focuses on combinations of causal conditions such as precipitation, temperature, soil moisture, groundwater trends, etc. Often, a consequence of considering these combinations of causal conditions is a compounding of uncertainty to a point at which results have only qualitative value. Embodiments can simplify drought analysis to what is assessed as the dominant causal mechanism, long-term precipitation deficits, and therefore produce highly quantitative results for future drought projection and statistical analysis. Whether water is manifest as streamflow, infiltration into aquifers, or snow that accumulates and melts, all water can be traced to precipitation. Embodiments can isolate this dominant variable such that coupling with other factors creates less “noise” and uncertainty, and drought prediction in any hydrologic venue can focus quantitatively on the root cause of droughts: cumulative rainfall deficits.

Yet another example advancement of embodiments is blending stochastic analysis of historical climate data with DCFs using either a well-defined percentile technique of climate projections referred to as a “Hybrid-Delta” approach, or an alternative technique that calculates DCF percentiles based on their ordered rank. In the Hybrid-Delta approach, historical climate and hydrologic timeseries values are adjusted up or down individually based on the historical percentile of an individual value relative to the projected future percentiles. Furthermore, the existing Hybrid-Delta approach is a U.S. Bureau of Reclamation (USBR) percentile technique that uses actual timeseries values, which are sorted, and then calculates DCFs by percentile. The weakness in this conventional approach as it is customarily applied by many planners, federal organizations, and water managers is that it preserves a historical sequence of events. For flood analysis, this is of little consequence, but for droughts, neither duration nor frequency can be changed synthetically. In an embodiment, the alternative technique includes applying DCFs to stochastically generated historical data, thereby creating degrees of freedom in the sequencing of monthly rainfall values such that frequency and duration can be adjusted in addition to intensity. The further example advancement of embodiments is blending generated DCFs with stochastically generated historical and future timeseries to project three example drought-related rainfall variables: frequency, duration, and intensity of cumulative rainfall deficits. In this example technique, GCMs are employed to produce future monthly rainfall values across daily rainfall totals, or alternatively as percentiles ranked according to daily rainfall totals. These are translated into DCFs that are applied to randomly generated historical patterns, e.g., hundreds of patterns, that preserve historical statistics for averages and ranges in a way that allows cumulative rainfall deficits to vary in future projections in their intensity, duration, and frequency. Embodiments thus provide a significant step forward, because so much traditional drought forecasting assumes that while historical hydrology may be wetter or drier, a sequence of monthly rainfall patterns will not change.

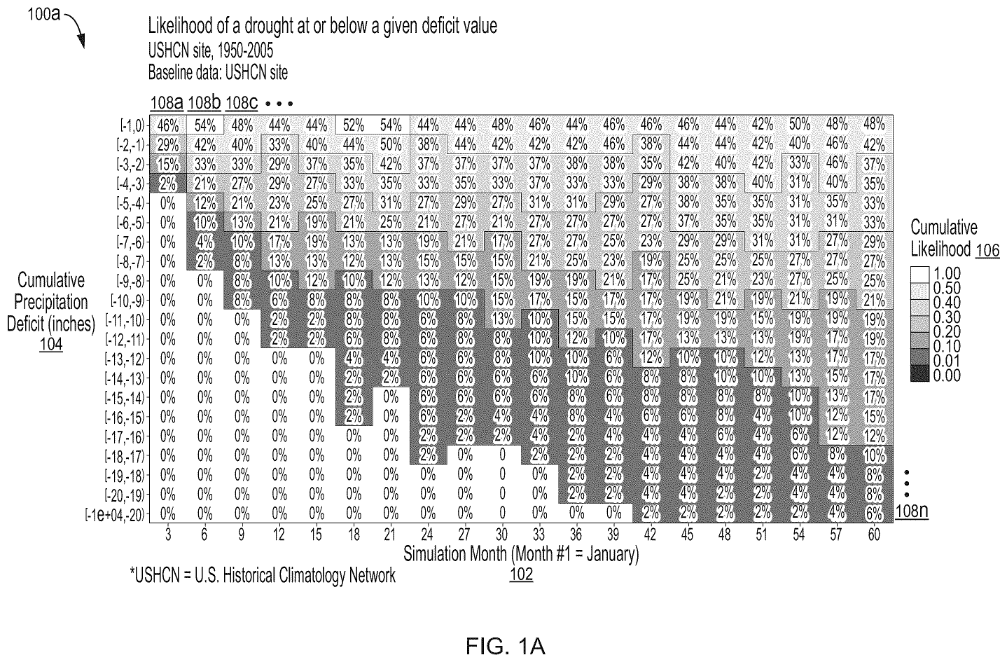

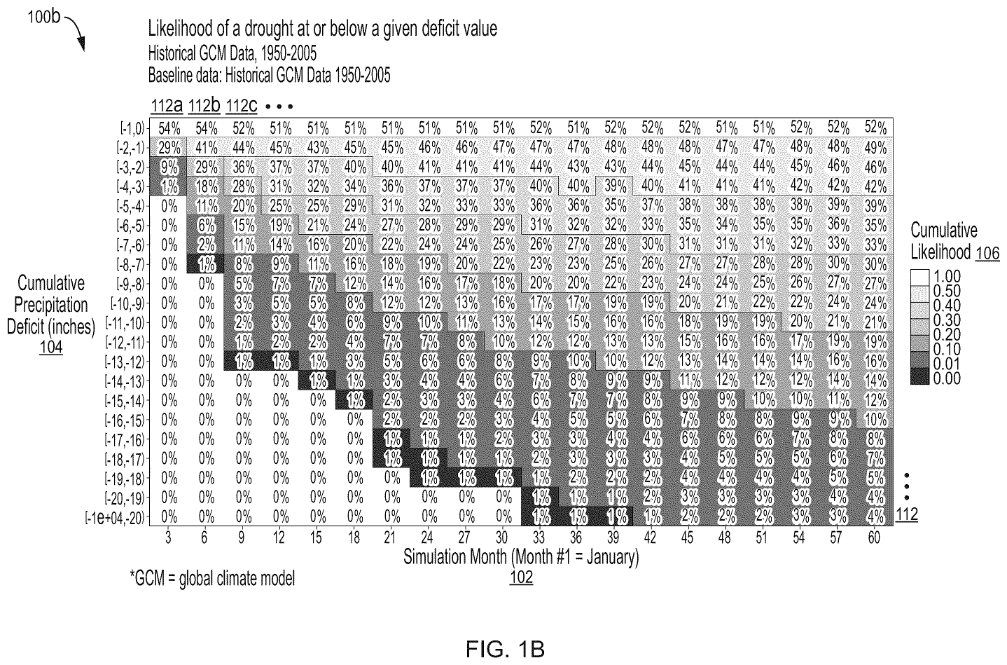

FIGS. 1A and 1B illustrate aspects of embodiments. FIGS. 1A and 1B illustrate an example climate model efficacy analysis method with example matrices 100a and 100b, respectively, of cumulative rainfall deficit frequency, intensity (magnitude of cumulative deficit), and duration, according to an embodiment. FIGS. 1A and 1B compare, visually and numerically, cumulative rainfall deficit statistics for a historic period in FIG. 1A with a simulated hindcast of the same historic period using an example ensemble of 32 GCMs in FIG. 1B. As shown in FIGS. 1A and 1B, deficit duration 102 is displayed on the horizontal x-axis, deficit magnitude 104 (in inches) is displayed on the vertical y-axis, and frequency 106 (i.e., likelihood) of any combination of the duration 102 and magnitude 104 is displayed as well as being color/shade-coded within matrix cells 108a-108n and 112a-112n, respectively. Side by side, these matrices 100a and 100b offer a good indication of the GCMs' ability to reproduce long-term rainfall deficits, a metric for which the GCMs are not necessarily calibrated, or “trained.”

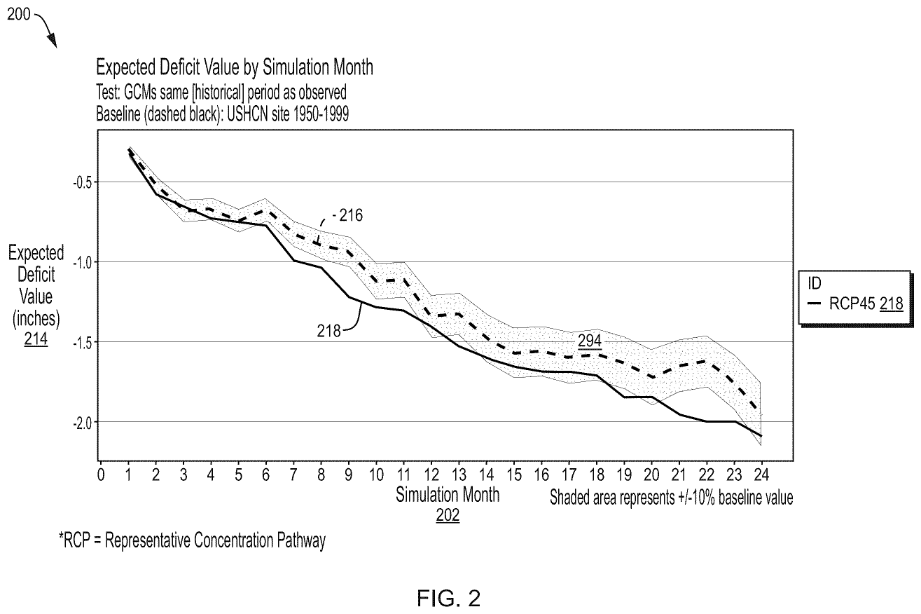

FIG. 2 illustrates aspects of an example analysis of efficacy of the ability of climate model(s) to reproduce long-term cumulative rainfall deficits and is a derivative of the information displayed in FIGS. 1A and 1B. FIG. 2 is an example graph 200 of expected values of cumulative rainfall deficit 214 versus duration in months 202 according to an embodiment. As shown in FIG. 2, dashed line 216 indicates historical rain gage data and solid line 218 indicates GCM hindcast results, while gray shading 294 indicates a 10% range above and below the gage data 216. For any given deficit duration 202 up to two to five years, discretized monthly, the graph 200 distills frequency values, which may also be interpreted as “likelihood at any given time,” and corresponding deficit intensity values into an expected value of cumulative deficit 214 using a weighted probability approach. Using the expected value 214 to characterize cumulative deficits is also an innovation within the scope of embodiments. In an embodiment, the margin of error 294 may be used to determine whether the GCM hindcast results 218 are generally acceptable. For instance, to be considered acceptable, the results 218 should either fit within the margin 294 or be close to it for the full time period 202.

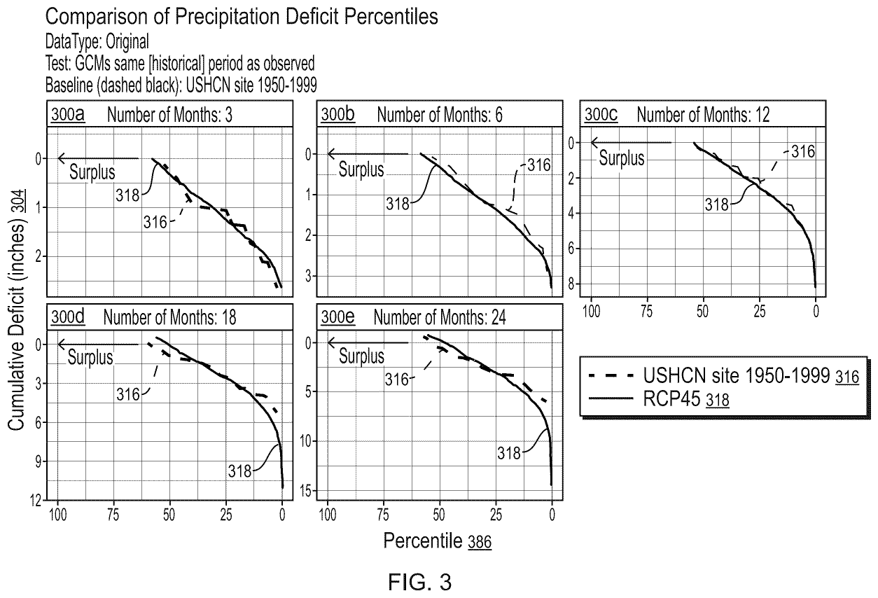

FIG. 3 illustrates aspects of an example analysis for determining efficacy of the ability of climate model(s) to reproduce long-term cumulative rainfall deficits and is also a derivative of information set forth in FIGS. 1A and 1B. FIG. 3 illustrates an example analysis of rainfall cumulative deficit. As shown in FIG. 3, solid line 318 indicates GCM ensemble cumulative deficits 304 in plots 300a, 300b, 300c, 300d, and 300e for months 3, 6, 12, 18, and 24, respectively, of a drought by percentile of values below a given value at each percentile 386; dashed line 316 indicates the same information using rain gage data. In an embodiment, for the GCMs to be suitable for direct drought projection, the GCM results 318 should align with the historic curves 316 for each of the durations in the plots 300a-300e. According to another embodiment, if the results 318 only align with a subset of the durations, then the GCMs may be used for drought projection for only those durations having a good hindcast fit.

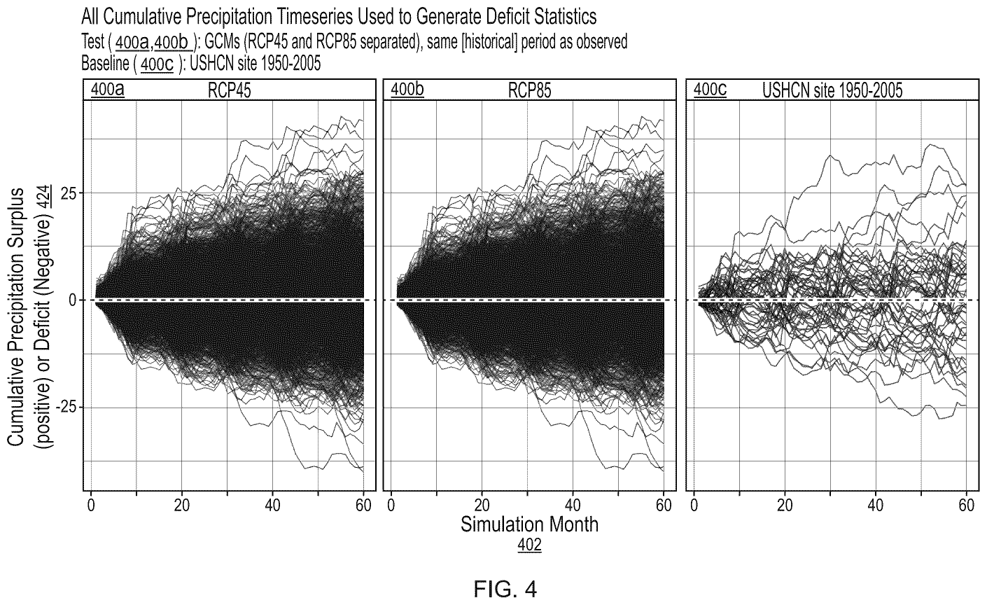

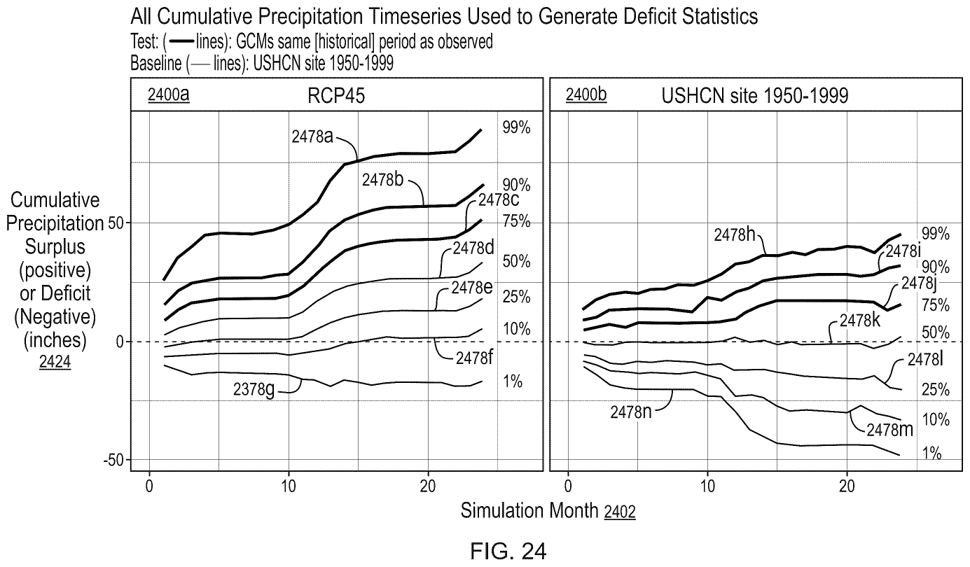

FIG. 4 illustrates aspects of an example analysis of efficacy of the ability of climate model(s) to reproduce long-term cumulative rainfall deficits and is the source of the information in FIGS. 1A and 1B. FIG. 4 illustrates example ranges 400a-400c of cumulative rainfall surplus and deficit 424 for simulation months 402 according to an embodiment. Lines in the plots 400a (RCP4.5) and 400b (RCP8.5) are individual five-year hindcasts by each GCM for each five-year period beginning with January in the period of record. Lines in the rightmost plot 400c are for the same five-year periods as the plots 400a and 400b, but are developed from an associated rain gage for comparison. In FIG. 4, the historic five-year deficits as measured by a rain gage for a region in the plot 400c are compared with GCM hindcasts of associated five-year deficits and surpluses 424 for the region in the plots 400a and 400b. While the example analyses illustrated in FIGS. 1A/1B, 2, and 3, respectively, are a combination of numeric and visual comparisons, this example analysis illustrated in FIG. 4 is mostly visual, and serves as an indication of potential bias in the GCMs with respect to long-term trends in cumulative statistics. In an embodiment, bias can be visually perceived if a range of cumulative deficits or cumulative surpluses in GCM hindcast results significantly exceeds an excursion of gage data traces, which is not the case in the example of FIG. 4, but which can be seen in FIG. 24 (described in detail hereinbelow) using selected percentiles of the traces.

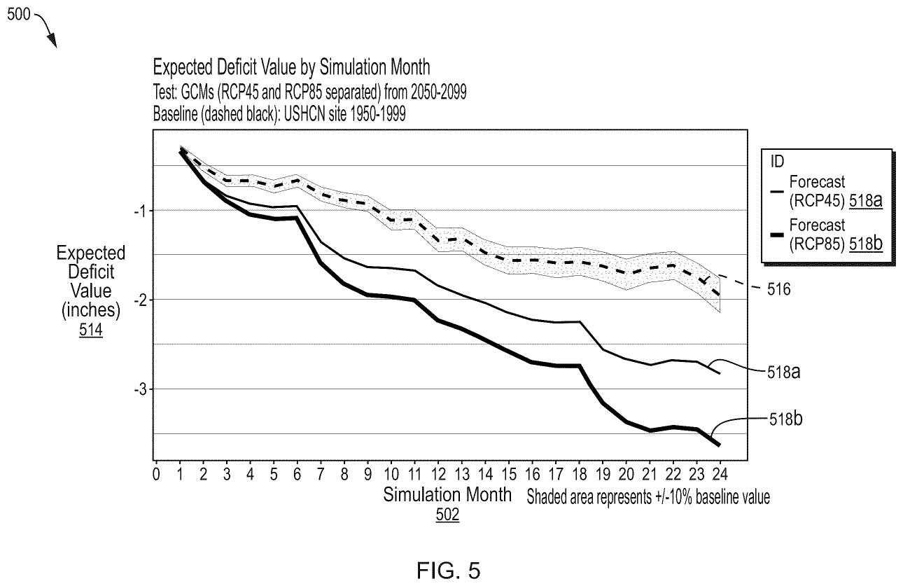

FIG. 5 illustrates a novel example approach to using climate model(s) for future forecasting. FIG. 5 is an example graph 500 illustrating GCM projection of future drought conditions with expected values of cumulative rainfall deficit 514 for simulation months 502 according to an embodiment. As shown in FIG. 5, dashed line 516 indicates historical rain gage data and solid lines 518a and 518b indicate future GCM projections for RCP45 and RCP85, respectively. In the plot 500, the future forecasts 518a and 518b suggest a much drier future climate beyond year 2050, with expected cumulative rainfall deficits being approximately 1.5 to 2 times of what they were historically. This is a major advancement in drought projection and preparation-embodiments can analyze cumulative impacts of changing climate specifically and quantitatively, and include example efficacy analyses of cumulative rainfall statistics to enable confident drought planning and projection.

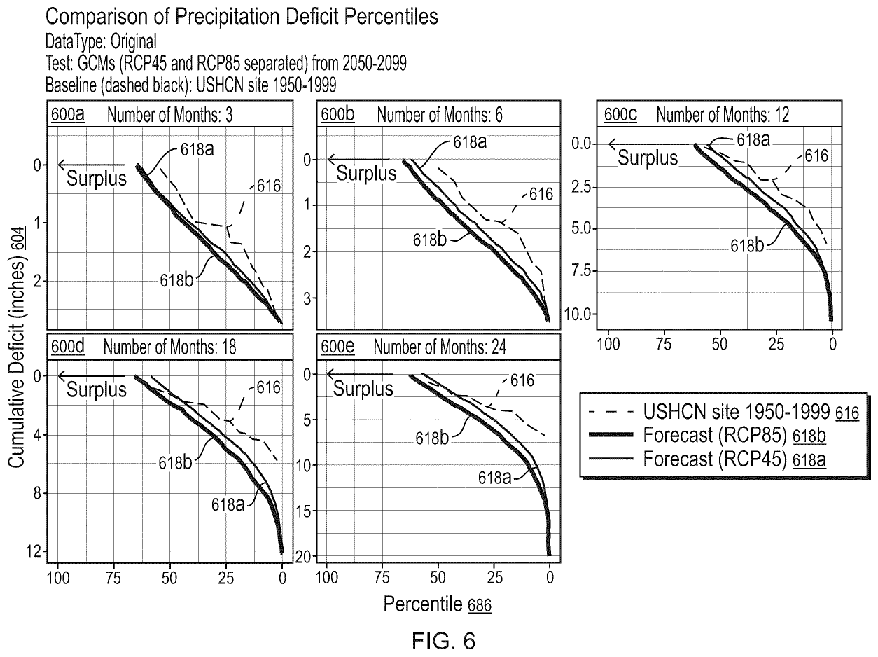

FIG. 6 illustrates another novel example approach for using climate model(s) for future forecasting. FIG. 6 depicts example GCM projections of future cumulative deficit 604 conditions in plots 600a, 600b, 600c, 600d, and 600e for months 3, 6, 12, 18, and 24, respectively, according to an embodiment. As shown in FIG. 6, dashed line 616 indicates historical rain gage data and solid lines 618a and 618b indicate future GCM projections for RCP45 and RCP85, respectively. The difference between FIG. 5 and FIG. 6 is the intended usage of future projections. FIG. 6 demonstrates future cumulative deficits 604 by percentile 686 at various durations, while FIG. 5 shows the expected deficit value 514 at each month 502.

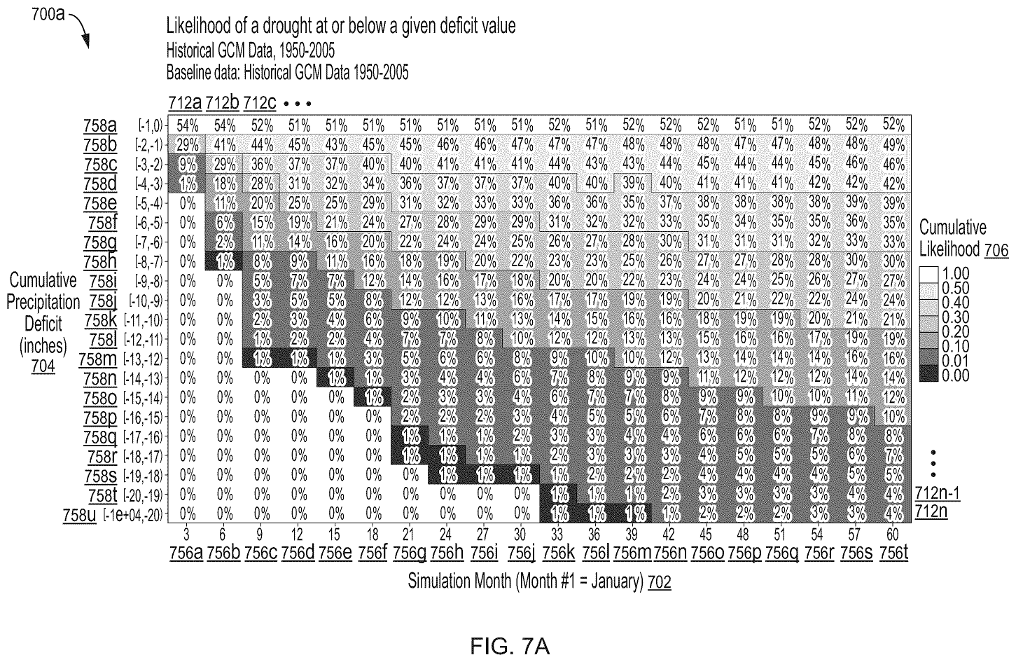

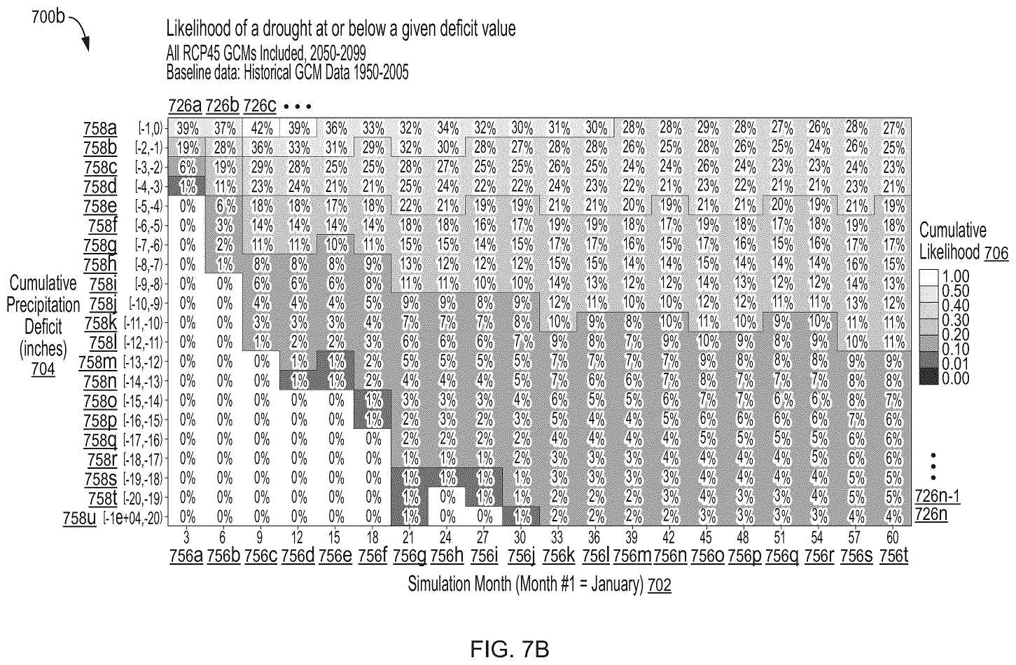

FIG. 7A is an example matrix 700a of climate model simulated historic rainfall deficits (GCM hindcast for years 1950-2005) according to an embodiment; the matrix 700a illustrates drought frequency, intensity, and duration. FIG. 7B is an example matrix 700b of projected future rainfall deficits (GCM projections for years 2050-2099) by the climate model(s) of FIG. 7A; the matrix 700b also illustrates drought frequency, intensity, and duration. Taken together, FIGS. 7A and 7B enable a visual and numeric comparison of climate model projections of future cumulative rainfall deficits in FIG. 7B with climate model hindcast values in FIG. 7A. As depicted in FIG. 7B, some extreme values of cumulative deficit 704 in the example matrix 700b show higher frequency/likelihood 706 in the future, e.g., a frequency of 5% in cell 726n-1 is greater than a corresponding frequency 4% in cell 712n-1. However, in general, the future predictions in the example 700b show lower frequencies or likelihood 706 of combinations of bins 758a-758u of cumulative deficits 704 and simulation months 702 of durations 756a-756t than in the historic example 700a of FIG. 7A, e.g., cells 726a-726c have values that are smaller than corresponding values in cells 712a-712c.

As described herein, the example efficacy analysis methods of embodiments can evaluate suitability of climate model(s) to directly simulate cumulative dry periods with statistical credibility at a given real-world geographic location, thus allowing for much more quantitative and confident projection of future rainfall/drought characteristics. In locations where climate model(s) do not adequately simulate dry periods, DCF methods of embodiments coupled with stochastic realizations of future conditions offer an alternative that can be used at any location. The example methods of embodiments offer numerous advantages compared to conventional techniques that rely on: (i) qualitative trends, (ii) qualitative composite drought indices, which can be fraught with compounding uncertainties associated with many variables, and (iii) traditional application of climate model(s) for drought forecasting, which may have deficiencies in their ability to reproduce long-term historic dry conditions.

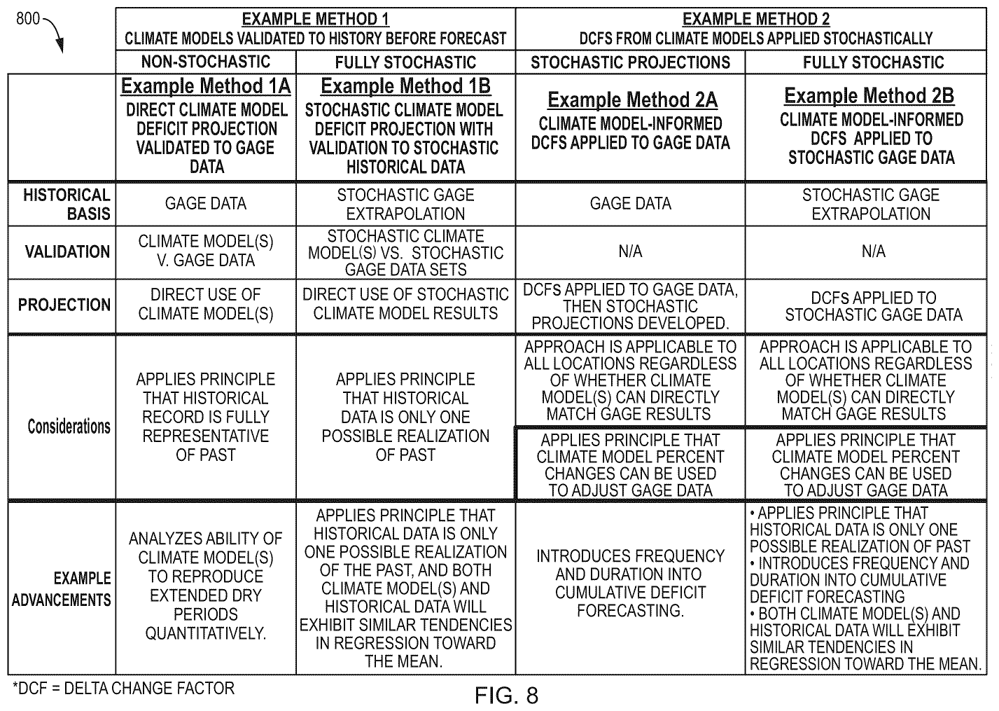

The graphics presented in FIGS. 1A, 1B, 2-6, 7A, and 7B, and derivatives of them, can be applied universally in any example methods of embodiments for projecting long-term cumulative rainfall deficits, an example framework 800 for which is illustrated in FIG. 8 and discussed hereinbelow. FIG. 8 depicts example methods for climate-induced rainfall deficit projections according to embodiments.

### Example Method 1A: Direct Climate Model Rainfall Deficit Projections Validated to Gage Data

In an embodiment, as shown in FIG. 8, example Method 1A is a method with which to compare simulated climate model hindcasts with historical long-term deficit statistics at a nearby gage. The example Method 1A can then be used for projection if the simulated climate model hindcasts demonstrate consistency with historical records. In early tests, the example efficacy analysis methods of embodiments have worked well in approximately 75% of regions evaluated across the U.S. when using, e.g., all available GCMs. The historical data to which climate model hindcast deficit statistics are compared can include the below non-limiting example forms:
a) Actual precipitation gage data: This is based in actual observations, e.g., measured rainfall data from a geographic location, and corresponds to the example Method 1A.
b) Stochastically synthesized ranges of possible historical conditions: This is based on expanded possibilities of what historical trends could have been, and corresponds to example Method 1B, described hereinbelow.

### Example Method 1B: Stochastic Climate Model Rainfall Deficit Projections with Validation to Stochastic Historical Data

In an embodiment, as shown in FIG. 8, with example Method 1B, both projected rainfall deficits and historical rain gage data may be a stochastically synthesized range of possible historical and projected deficits. If climate model(s) are validated through application of the example Method 1A, then climate model projection(s) can be used directly as a basis to stochastically generate a range of future cumulative rainfall deficits.

As noted, an example benefit of the example efficacy analysis methods of embodiments is a determination of whether directly using climate model output is actually suitable for drought planning and projection. If climate model(s) prove to be poor estimators of long-term cumulative rainfall deficit patterns, two example DCF-based methods of embodiments can bypass this problem by basing projections on rain gage data, altered by climate model-produced DCFs. These are referred to as example Methods 2A and 2B. The example technique of using DCFs applied for cumulative rainfall deficits with variable durations and frequencies has been made possible by embodiments.

### Example Method 2A: Climate Model-Informed DCFs Applied to Rain Gage Data

The traditional Hybrid-Delta approach of applying DCFs only to historical rain gage data, as frequently employed and approved by federal and state agencies and other water managers, has multiple drawbacks. For instance, conventional Hybrid-Delta is an approach that does not verify adequacy of climate model(s) for this purpose, and further, it only varies intensity. Thus, nothing can be suggested or learned about future variations in frequency or duration, which are important considerations in drought projection and planning.

In an embodiment, as shown in FIG. 8, the example Method 2A uses rain gage data as a basis for historical cumulative deficit calculations, thus eliminating a need to directly validate long-term cumulative precipitation trends of climate model(s) to reproduce cumulative deficits that match a historical pattern. The example Method 2A then alters the gage cumulative deficits using two different DCF approaches to project future cumulative deficits. The projected cumulative deficits are stochastically generated from the DCF altered gage data, thus making this approach applicable to all sites. The example Method 2A can apply a traditional DCF method to gage data, and then extend these future predictions stochastically to incorporate changes in frequency and duration.

### Example Method 2B: Climate Model-Informed DCFs Applied to Stochastically Generated Gage Data

In an embodiment, as shown in FIG. 8, the example Method 2B, like the example Method 2A, also uses gage data and thus is applicable to all sites. Instead of applying climate model-produced DCF(s) to historical gage data directly, the example Method 2B shifts to stochastic generation of historical drought patterns, recognizing that actual observed historical patterns represent only one realization of what was possible in a historical period. Stochastically generated historical monthly rainfall timeseries are based upon a principle that collectively, they represent a range of conditions that plausibly could have occurred in the past. Hundreds or thousands of possible historical realizations can be generated and overall statistics of these with respect to historic gage data can be verified, but with less need for accurate matches because a historical gage is accepted as only one possibility. DCFs are applied to these stochastic historical timeseries; specifically, DCFs are applied to each stochastically generated cumulative deficit series. In this way, climate model projection(s) are still used, but their results are generalized, and sequential weaknesses are removed if they cannot reproduce long-term dry patterns. The stochastic historic monthly rainfall timeseries, which adjust frequency and duration of historic deficits as well as intensity, are adjusted value by value up or down based on corresponding DCFs of monthly precipitation. In this method, random stochastic sequencing of historical events and impacts of emissions-based climate forecasts both combine to affect predictions of future cumulative rainfall deficit duration, intensity, and frequency. Traditionally, and in accordance with some current federal practices, DCFs have generally only been applied to historical gage data, which does not allow drought frequency or duration to change in future projections.

The example methods of embodiments described herein provide new approaches to quantitative prediction of future rainfall deficit statistics. Some embodiments may apply both the example Methods 1A/B and 2A/B concurrently, and results can be compared. If the results agree on future rainfall deficit statistics, such corroboration is of great value in an area of forecasting fraught with uncertainty. If the results are reasonably close but with moderate differences, these differences can be used to confidently project a range of future rainfall deficit statistics for planning purposes. Further, if the example Methods 1A and 1B digress significantly from rain gage produced results, then the example Methods 2A and 2B offer a means to produce quantitative projections so sorely lacking in existing approaches.

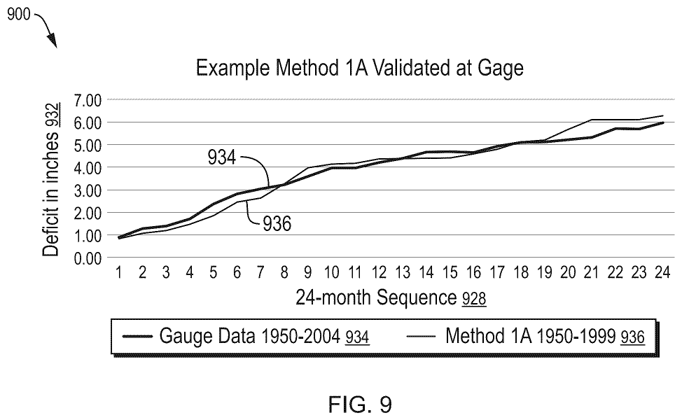

FIG. 9 is an example graph 900 illustrating Method 1A (FIG. 8) climate model validation according to an embodiment. FIG. 9 illustrates results for a baseline period 928 and compares month-by-month expected deficits 932 from a rain gage 934 with results 936 from 32 GCM hindcasts using the example Method 1A. The results 936 make use of “Expected Value” of deficit results (e.g., FIG. 2) for an “Expected Value” analysis for cumulative rainfall over any given duration. FIG. 9 demonstrates that in this case, GCMs can accurately reproduce historical rainfall deficit, duration, and frequency statistics when using the GCM output directly, and the example Method 1A can be used for future predictions.

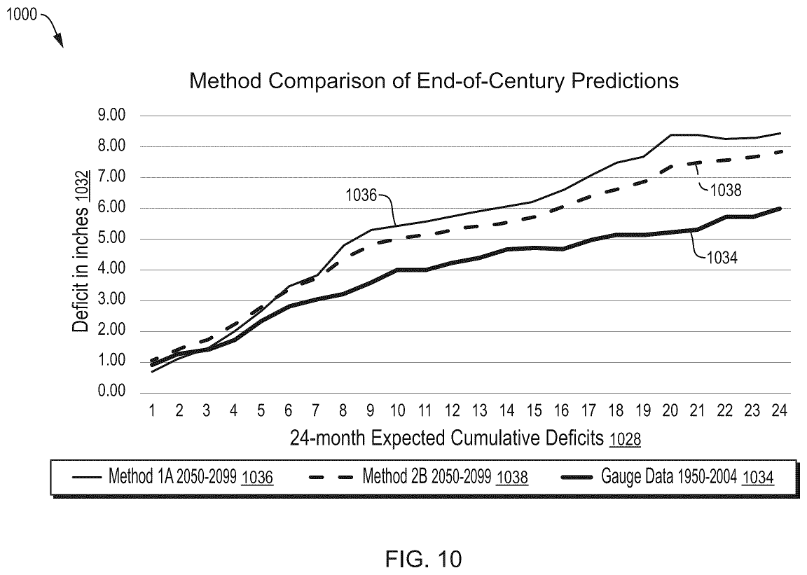

FIG. 10 is an example graph 1000 illustrating a comparison of end-of-century projections 1036 using the example Method 1A for direct use of climate model data and end-of-century projections 1038 using the example Method 2B for DCFs applied to stochastic rain gage data according to an embodiment. The projections 1036 and 1038 are contrasted with baseline conditions 1034 illustrated by use of the example Method 1A on local rain gage data from years 1950-2004. The results 1036 and 1038 make use of “Expected Value” of deficit results (e.g., FIG. 2) for the “Expected Value” analysis for cumulative rainfall over any given duration 1028. FIG. 10 demonstrates that in this location, deficits 1032 are predicted to increase. Comparison of the example Methods 1A and 2B also shows that the stochastic method (i.e., Method 2B) will generally provide slightly different results than the direct use (i.e., Method 1A) of monthly rainfall data. Stochastic results as compared to direct use results may include a broader range of plausible past conditions.

Embodiments supply innovations with valuable benefits including, for non-limiting examples:
a) Climate model(s) can be analyzed to determine their suitability for future drought projections—not all of them can be assumed to be useful in this realm.
b) Embodiments can generate unique and innovative visualizations for the leading indicator of droughts—long-term rainfall deficits. The visualizations can be used to describe and compare historical and future drought-related statistics of frequency, duration, and intensity.
c) Where climate model(s) do not produce faithful hindcasts of historical long-term dry patterns, the problem of month-to-month sequencing can be solved with stochastic sampling of historic values, adjusted as individual values with “change factors” derived from climate model(s), where trends in rainfall for each calendar month are preserved, but sequencing is handled by the stochastic generation.
d) Where both the direct climate model deficit projections and the climate model-informed DCF deficit projections work, results may be interpreted as solidly corroborated by two independent approaches.

Drought severity can be characterized by the cumulative rainfall deficit over a given time period, the effects of temperature on evaporation, antecedent soil moisture, etc. None of these factors, on its own, is capable of expressing the severity of a drought, and more importantly, combining them in predictive ways can be extraordinarily complex and speculative due to the compounding uncertainty or combined probability of coupled probabilities.

To date, no known compilation of cross-probabilistic statistics of future drought duration and intensity-which is numerical enough to be simulated in deterministic models exists for various hydro-regions of the U.S. This is partly because existing research on drought forecasting has focused on multiple causal factors, and their joint probabilities are difficult to assess with confidence, especially using GCMs that are not sufficiently tuned to reproduce long-term trends in dry conditions. Water managers and providers who do turn to GCMs risk not knowing how well any given GCM or an ensemble of multiple GCMs can create extended dry conditions-all they know is how well rainfall probability is defined in any given future month. The probability of drier than normal conditions from one month to the next, or from one year to the next, is generally assumed by traditional approaches, but not verified. Further, conventional water simulation models that rely, somewhat blindly, on GCMs, assume that cross-coupled temperature and precipitation projections are credibly matched month to month, and this is not a scientifically supported assertion.

To combat the above and other problems with existing approaches, embodiments analyze climate model(s), e.g., GCM(s), to determine if they can credibly generate long-term dry periods reflective of historical statistics for cumulative rainfall deficits. This leads to much more confident use of climate model(s), or the use of innovative alternative, DCF-based approaches, for future drought prediction, planning, and preparedness. Embodiments can also isolate a dominant drought variable to avoid complexities of cross-coupled factors that may or may not be as precisely linked through time as the climate model(s) may suggest. Despite the many factors that lead to drought and drought persistence, the fundamental root cause is a lack of water, which originates in one form or another as precipitation.

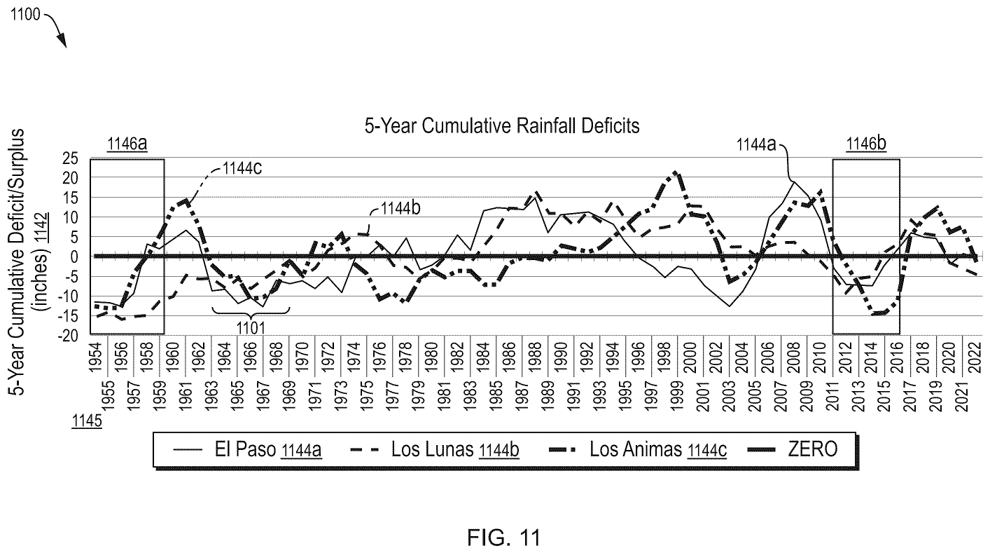

FIG. 11 is a graph 1100 illustrating a demonstration of cumulative rainfall deficit 1142 versus years 1145 and showing that cumulative rainfall deficit 1142 is a reliable indicator of drought conditions, according to an embodiment. As depicted in FIG. 11, boxes 1146a and 1146b on the left and right sides, respectively, of the plot 1100 delineate two benchmark droughts used for Texas water supply planning.

FIG. 11 illustrates that cumulative precipitation deficit is indeed a representative indicator of drought on its own, even absent other factors. The graph 1100 depicts historical five-year cumulative precipitation deficits 1142 in three locations in or near the Upper Rio Grande River Basin: El Paso, Texas 1144a; Los Lunas, New Mexico 1144b; and Las Animas, Colorado 1144c. The two periods 1146a and 1146b in which the cumulative rainfall deficits of all three sites were at their lowest together correspond exactly with the two historical droughts that Texas water providers use as benchmarks to determine future water supply reliability, i.e., the drought of the 1950s and the drought of the early 2010s. Of note, as indicated by region 1101, are the simultaneous low (high negative) values of cumulative deficit in the 1960s, another period known in Texas as having been a significant drought. This demonstrates that cumulative rainfall deficit is a useful indicator of full drought conditions and follows the principle that lack of water is fundamentally the root cause of every drought. Certain embodiments may leverage the foregoing principle.

Examples of major quantitative advancements in drought prediction delivered by embodiments include not only transforming drought indicators into cumulative rainfall deficits, which can be extracted from climate model(s), but also providing example methods to assess efficacy of climate model(s) to produce credible cumulative rainfall deficits. Another example major advancement of embodiments is coupling of DCF(s), a common output from climate model(s) that are applied to already-sequenced historical timeseries, with stochastically sequenced scenarios vetted against historical statistics, thereby allowing future projections of drought to vary in frequency, intensity and duration.

Moreover, embodiments provide a major advancement in prediction of future drought frequency, duration, and intensity by, for example, (a) isolating the most predictive variable in the form of cumulative rainfall deficits month-over-month and year-over-year, and (b) analyzing efficacy of climate model(s), e.g., GCM(s), and their ability to simulate extended dry periods, before employing the climate model(s) for drought prediction.

### Example Methods 1A and 1B: Direct Climate Model Rainfall Deficit Projection

The example Methods 1A and 1B (FIG. 8) may be implemented using the R computer programming language or any other suitable programming language known in the art. In addition, the example Methods 1A and 1B may include one or more of the following steps, for non-limiting examples:
a) For a site or region, collect climate model dataset(s), e.g., downscaled dataset(s) at a monthly timestep for available climate models, e.g., all available GCMs and/or selected RCPs. This process may be used with CMIP5 models and RCPs 4.5 and 8.5 as well as future phases of CMIP (e.g., CMIP6, etc.) and/or new concentration pathways.
b) Collect historical monthly rain gage data for the site/region from a representative gage with a long record, preferably dating back to year 1950.
c) Process the climate model data to produce a hindcast to match the period of record from the rain gage and use the hindcast with the rain gage data (e.g., up to 60 months per period) to generate graphical figures represented by one or more of the example efficacy analysis techniques illustrated herein (e.g., FIGS. 1A, 1B, 2-4, and 19-30). This may include examining, e.g., five-year period(s) or shorter in the rain gage record beginning in month X (generally January but not required), and, e.g., five-year period(s) in climate model combination(s) beginning in that same month to generate, for non-limiting examples:
   i. Cumulative rainfall deficit frequency/intensity/duration matrices.
   ii. Expected value of cumulative rainfall deficit for each month in, e.g., up to a five-year period.
   iii. Percentile plots for cumulative deficits over, e.g., 6, 12, 24, 36, 48, and 60 months.
   iv. Individual cumulative deficit and surplus traces and percentile of traces for, e.g., five-year combination(s) of GCM/RCP, and a separate comparative visualization of the same traces for the rain gage.
d) Determine whether direct use of climate model(s) for the site can be used quantitatively for future precipitation deficit projections.
e) If the example efficacy analysis(es) indicate that the direct use of the climate model(s) (i.e., example Method 1A or 1B) adequately reproduces historical long-term deficit statistics, then apply the climate model(s) in forecast mode for a selected future period, e.g., the period of years 2050-2099. Otherwise, if the example efficacy analysis(es) indicate that the direct use of the climate model(s) in total over- or under-represent historical cumulative rainfall deficits with a clear and consistent bias, then employ the climate model(s) using DCFs (i.e., example Method 2A or 2B) applied to gage data to make projections.
f) Assess results for future projections of cumulative rainfall deficit frequency, intensity and duration for dry periods for, e.g., up to five years. Note that results can also guide synthesis of simulation scenarios for system-specific hydrologic and water supply operations models, etc.

For calculations described hereinbelow, the term “duration” may refer to a study period of time for calculating given statistic(s). In some examples, a duration may range from two to five years.

### Example Collection of Climate Model Data

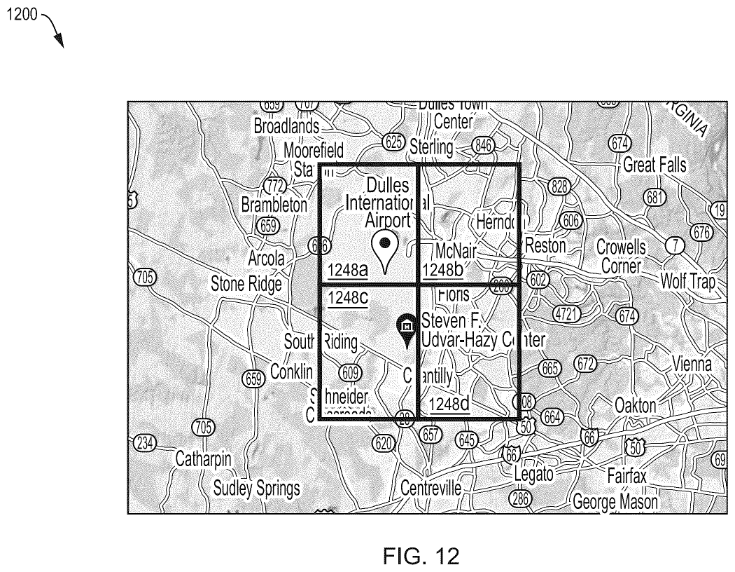

Embodiments may use publicly available climate data. For instance, an embodiment, may use publicly available, e.g., GCM CMIP5, projections. GCM CMIP5 projections can be downloaded from a range of different sources such as the USBR's data portal or the U.S. National Aeronautics and Space Administration (NASA) Center for Climate Simulation's NASA Earth Exchange Global Daily Downscaled Projections (NEX-GDDP). The data provided through the foregoing portals may come in Network Common Data Form (netCDF) file format, which contains requested information such as number models and selected emission scenarios. For this example application, CMIP5 projections may be downloaded that are representative of two emission scenarios, e.g., RCP4.5 and RCP8.5, for a period from years 1950 to 2100. An optional downscaling method selected for the data may be the Localized Constructed Analogs (LOCA) method that provides GCM output at a daily timestep and spatial resolution of 1/16 degree) (°, i.e., approximately 6.9 kilometer (km) grid cells. An example is provided in FIG. 12 that illustrates grid cell size and coverage over Dulles International Airport in Virginia. FIG. 12 is an image 1200 illustrating example GCM grid cells ( 1/16°) for data downloading according to an embodiment. As shown in FIG. 12, boxes 1248a-1248d delineate the grid cells used for this site's GCM data.

In an embodiment, for each location, daily precipitation volumes may be extracted from a netCDF file, e.g., through use of an R programming script, and may be processed for each climate model and emission scenario separately. This processing may include, for non-limiting examples:
a) Daily rainfall volumes may be provided for multiple grid cells in a desired location. These daily rainfall volumes may be averaged spatially using a mean to create a timeseries of daily rainfall volumes for each model and emission scenario.
b) The daily rainfall volume timeseries may then be aggregated to create a timeseries of monthly rainfall volumes for each model and emission scenario.

The above-mentioned monthly rainfall volume timeseries may then serve as input into a cumulative precipitation calculation, described hereinbelow.

### Example Collection of Historical Monthly Rain Gage Data

An embodiment may collect historical monthly rain gage data for a site or region from a representative rain gage with a long record, preferably dating back to 1950. Embodiments can obtain rain gage data from a wide variety of sources, including the U.S. Historical Climatology Network (USHCN), which provides rain gage information for sites with a long record length, data completeness, and historical stability.

### Example Processing of Climate Model Hindcast Data and Rain Gage Data for Efficacy Analysis(es)

In an embodiment, the example calculations described hereinbelow are presented in the context of example Methods 1A and 1B for purposes of illustration, but the example calculations and their associated visualizations can be applied to all the example embodiments described herein.

### Example Calculations

In an embodiment, once timeseries data, e.g., monthly timeseries, have been collected for a site from both climate model(s) and a rain gage, these data may be processed to generate visualization(s), e.g., FIGS. 1A, 1B, 2-4, and 19-30, representing the example efficacy analysis techniques(s) described herein. According to another embodiment, timeseries data may first be processed to calculate cumulative precipitation and/or cumulative precipitation deficit for durations ranging from, e.g., 1 month to 60 months.

### Example Cumulative Precipitation Calculation

In an embodiment, cumulative precipitation may include a total amount of precipitation for a given duration “D.” This may be calculated on a, e.g., monthly, timestep. According to another embodiment, cumulative precipitation can be calculated for any timeseries of data, including historic data from a rain gage and for climate model precipitation output. In yet another embodiment, cumulative precipitation can also include stochastically generated timeseries data.

In an embodiment, looking at an example duration of three months, the cumulative precipitation can be calculated using the following equation:

$$Cumulative {Precipitation}_{3 month} = {\sum }_{0}^{3 month} monthly precipitation$$

According to another embodiment, the same calculation can be done for any duration drought, as shown below:

$$Cumulative {Precipitation}_{D} = {\sum }_{0}^{D} monthly precipitation$$

where D is duration of drought in months

### Example Cumulative Precipitation Deficit Calculation

In an embodiment, cumulative precipitation deficit may be a difference between cumulative precipitation for a primary timeseries of duration D and cumulative precipitation of a baseline precipitation timeseries of duration D. The larger the negative value, the larger the estimated precipitation deficit. A positive value may indicate a surplus of precipitation compared to a baseline timeseries. According to another embodiment, cumulative precipitation deficit can be calculated for historically observed data, hindcast climate model data, or future climate model data, through changing a primary and/or baseline timeseries used in an analysis.

In an embodiment, a baseline precipitation timeseries may first be calculated by defining a rain gage dataset, i.e., historical observed data from a rain gage, and a period, e.g., years 1950-2004. This monthly timeseries may then be averaged by month using a mean to generate average monthly precipitation volumes for the dataset in the defined period. The average monthly values may then be used to calculate cumulative precipitation for any duration D for the baseline precipitation timeseries.

In an embodiment, an example calculation of cumulative precipitation deficit for a three-month long drought is provided by the following equation:

$$Cumulative Precipitation {Deficit}_{3 month} = {\sum }_{0}^{3 month} ( {precipitation}_{n} - {baseline}_{n} )$$

where precipitationₙ=monthly precipitation from month n in primary timeseries
baselineₙ=average monthly precipitation from month n in baseline dataset

According to another embodiment, the same calculation can be done for any duration drought, as shown below:

$$Cumulative Precipitation {Deficit}_{D} = {\sum }_{0}^{D} ( {precipitation}_{n} - {baseline}_{n} )$$

where D is duration of drought in months
precipitationₙ=monthly precipitation from month n in primary timeseries
baselineₙ=average monthly precipitation from month n in baseline dataset

### Example Cumulative Precipitation Deficit Statistics

In an embodiment, cumulative precipitation deficit statistics enable characterization of drought, e.g., precipitation deficit in terms of frequency, intensity and duration. According to another embodiment, cumulative precipitation deficit statistics may be calculated by determining a fraction of timeseries of duration D in a primary dataset that have a cumulative precipitation deficit equal to or more severe than a value or magnitude “Mag.” Calculating these statistics may include the following steps, for non-limiting examples:
a) Define a baseline dataset and period. e.g., historical rain gage data from years 1950-2004, and calculate monthly mean precipitation.
b) Define a primary dataset and period, e.g., GCM hindcast data from 32 models from years 1950-2004.
c) Define a duration D in months.
d) Define a start month X (e.g., January).
e) Define a set Precipts of size P, where each element in the set is a monthly precipitation timeseries starting in month X and of duration D.
f) Calculate cumulative precipitation for each of the elements in the set Precipts.
g) Calculate cumulative precipitation deficit for each of the elements in the set Precipts using the baseline dataset and period defined in step (a).
h) Calculate likelihood by dividing the number of elements in Precipts with a cumulative precipitation deficit equal to or more severe (larger negative number) than Mag by the total number of elements P.

Multiple example methods may be used to generate the set Precipts from rain gage and climate model data and are described hereinbelow.

### Example Visualizations

### Example Cumulative Precipitation Deficit Cumulative Likelihood Matrix

In an embodiment, an example method for visualizing cumulative precipitation deficit is through a cumulative precipitation deficit likelihood matrix. FIGS. 7A and 7B (also described hereinabove) illustrate example cumulative precipitation deficit likelihood matrices. On the y-axis 704, deficits of various magnitudes (intensity) Mag are divided into discrete “bins” 758a-758u defining specific cumulative precipitation deficits in inches of rainfall. On the x-axis 702, each column 756a-756t refers to a specific drought duration D up to the longest duration Dₘₐₓ being investigated. Each cell 712a-712n shows the percentage of monthly precipitation timeseries in the set Precipₜₛ from the primary dataset that had a magnitude Mag equal to or more severe than the deficits in that bin.

### Example Weighted Deficit/Expected Value of Cumulative Rainfall Deficit

In an embodiment, calculations of frequency from a cumulative precipitation deficit likelihood matrix may be used to compute a weighted deficit for each duration. An example of this visualization is shown in FIG. 2 (described hereinabove). Each weighted deficit 514 value is calculated from a column of a corresponding precipitation deficit likelihood matrix. It should be noted that individual likelihood for each bin is used in the example of FIG. 2 instead of cumulative likelihood. To continue, the percentage (likelihood) of each cell is multiplied by the median value for the deficit of the cell. For example, using the three-month column 756a from FIG. 7A, the weighted deficit 514 is calculated using the following equation:

$$\begin{matrix}Weighted {Deficit}_{3 month} = 54 \% \times ( - 0.5 ) + 29 \% \times ( - 1.5 ) + \\ 9 \% \times ( - 2.5 ) + 1 \% \times ( - 3.5 ) \\ = - 0.965 inches\end{matrix}$$

Which corresponds to a generalized equation to calculate the weighted deficit:

$$Weighted {Deficit}_{n month} = {\sum }_{0}^{n} frequency \times deficit$$

where frequency is in percentage and deficit is the median value of the cell in the matrix

### Example Intensity Duration and Frequency of Cumulative Precipitation Deficit

Plotting order-ranked data may be used in estimating probabilities of extreme weather events. Typically, observations such as annual extremes of a period of N years may be ranked in order of intensity and plotted on probability paper. A statistical model may then be fit to the order-ranked data, by which return periods of specific extreme events may be estimated. A key question in this technique is: What is a cumulative probability P that should be associated with a sample of rank “m”? This issue of the so-called plotting positions has been debated for almost a century, and a number of plotting rules and approaches have been proposed. In an embodiment, the plotting position below may be used for non-limiting example:

$$P = m / ( N + 1 )$$

Where:
a) P is a plotting position representing AEP.
b) N is number of two-year timeseries in a dataset. This means that GCM models may have a larger N value because they may have 32 models that generate different timeseries data.
c) m is the rank.

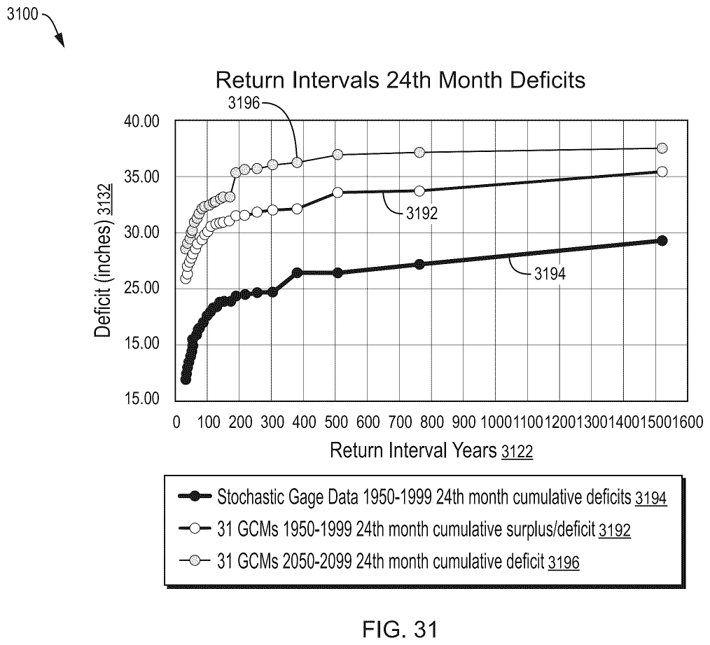

According to another embodiment, the plotting position (independent variable) can be graphed against the cumulative deficits (dependent variable) to provide an estimate of AEP or its inverse, i.e., return intervals. The example graph 3100 in FIG. 31 (described hereinbelow) illustrates results of this analysis. It is noted that the results 3192, 3194, and 3196 can be generated directly from data or fit to a logarithmic function that can be extrapolated to estimate return intervals.

### Example Individual Cumulative Deficit and Surplus Traces for Climate Model(s) and Rain Gage

In an embodiment, weighted deficits may provide a succinct way of comparing overall precipitation deficit statistics. The example graphs 400a-400c in FIG. 4 show cumulative precipitation timeseries that may be used to create likelihood matrices and ultimately weighted deficits that are presented. FIG. 4 is distinct from most of the other figures described herein in that FIG. 4 shows both timeseries with cumulative precipitation surpluses (positive numbers) and those with cumulative precipitation deficits (negative numbers). The lines in the two left-most plots 400a and 400b show the two-year cumulative precipitation timeseries considered for the RCP4.5 and RCP8.5 hindcast data, while the lines in the rightmost plot 400c show the two-year timeseries considered for the observed data.

The example graphs 400a-400c in FIG. 4 may facilitate determining whether climate model data (lines in the two left-most plots 400a and 400b) includes timeseries with deficits and surpluses in the same general range as those found in an observed dataset (lines in the right-most plot 400c).

### Example Applications of Calculations and Visualizations for Efficacy Analysis

In an embodiment, the example calculations and visualizations described hereinabove can be applied to evaluate whether climate model output can effectively reproduce observed precipitation deficit frequency, intensity, and duration. According to another embodiment, the example Method 1A may determine whether climate model(s) are able to reproduce these statistics (i.e., precipitation deficit duration, frequency, and intensity) when directly applied, while the example Method 1B may do the same for stochastically generated hindcasts and projections.
a) The example Method 1A may use historical rain gage data during a hindcast period, e.g., years 1950-2005 for CMIP5, as a baseline dataset and period. The example Method 1B may generate, e.g., hundreds or thousands of timeseries, as a baseline dataset and period using rain gage data as a source dataset for stochastic realizations.
b) Both the example Methods 1A and 1B may use gage data as a dataset against which climate model results are validated. The same hindcast period may be used for a baseline period to ensure that simulated period results match gage period results for the baseline period.
c) The two example Methods 1A and 1B may use different approaches to define a set of, e.g., monthly precipitation timeseries Precipₜₛ by using direct climate model monthly rainfall output.
   i. For the example Method 1A, this may include, for non-limiting example:
      1) For each climate model, take each two-year timeseries that appears in a primary period, e.g., monthly precipitation values for a single GCM in years 1950-1951, 1951-1952, . . . , 2004-2005.
      2) Filter the two-year timeseries down to the desired duration length D, e.g., if D is three months, then take the first three months of the two-year timeseries.
      3) Repeat this process for each climate model that will be used in a primary dataset. Combine all these timeseries from each climate model to create a final set Precipₜₛ.
   ii. For the example Method 1B, this may include, for non-limiting example:
      1) For each climate model, take each two-year timeseries that appears in the primary period, e.g., monthly precipitation values for a single GCM in years 1950-1951, 1951-1952, . . . , 2004-2005.
      2) Filter the two-year timeseries down to the desired duration length D, e.g., if D is three months, then take the first three months of the two-year timeseries.
      3) Repeat this process for each climate model that will be used in a primary dataset.
      4) Combine all these timeseries from each climate model to create a dataset used to generate a base dataset Precipₜₛ.
      5) Stochastically sample the base dataset to produce as many stochastically generated series as deemed necessary to produce the final set Precipₜₛ.

In an embodiment, the example Methods 2A and 2B may not rely upon the adequacy of climate model(s) to directly reproduce results of a nearby rain gage. Instead, the example Methods 2A and 2B may use the nearby rain gage as a dataset for a baseline period. This baseline period can be a single realization of a baseline period as represented by direct use of the rain gage data for a selected time period (i.e., the example Method 2A). This baseline period can expand the number of timeseries by stochastically generating, e.g., hundreds or thousands of baseline timeseries using the gage baseline period as a source dataset. The baseline period or stochastically generated baseline periods may then be adjusted using climate model-produced DCF(s) to produce desired future timeseries.

### Example Determination Whether Direct Use of Climate Model(s) Validates Use of Example Methods 1A and 1B for Future Precipitation Deficit Projections

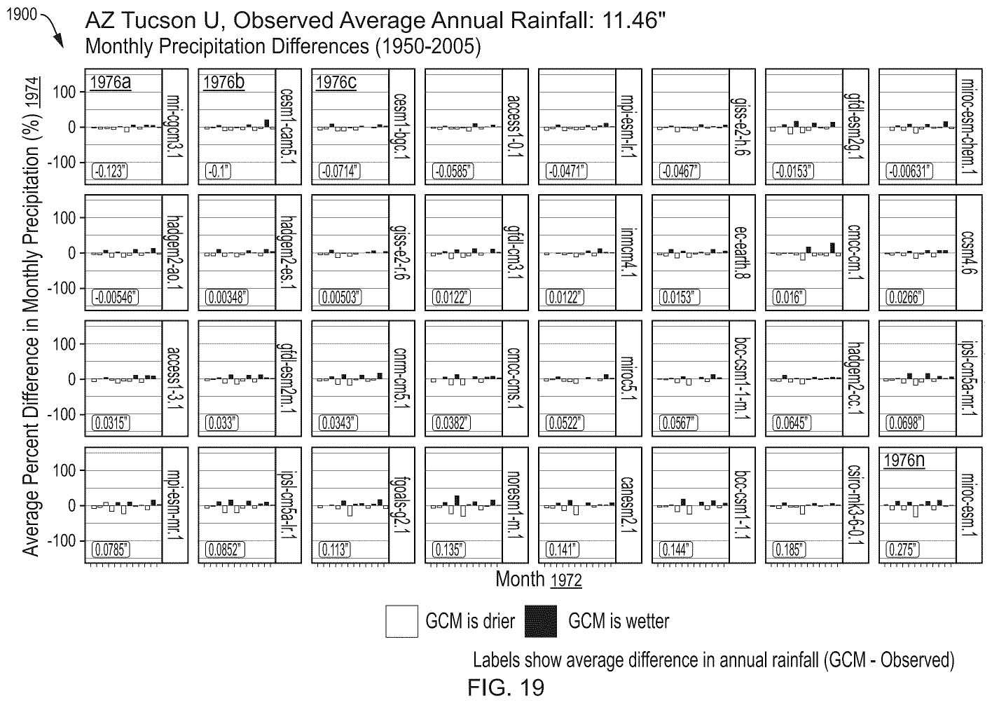

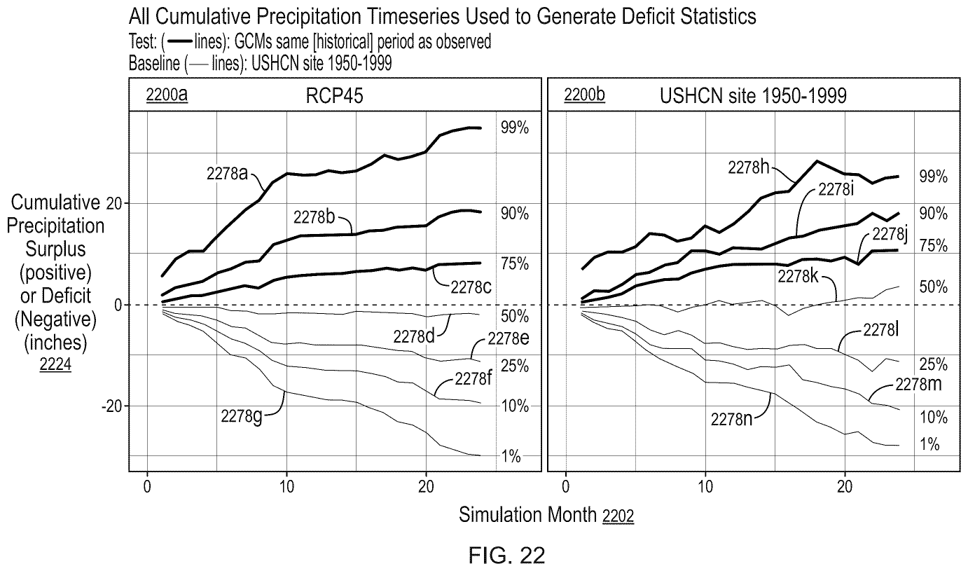

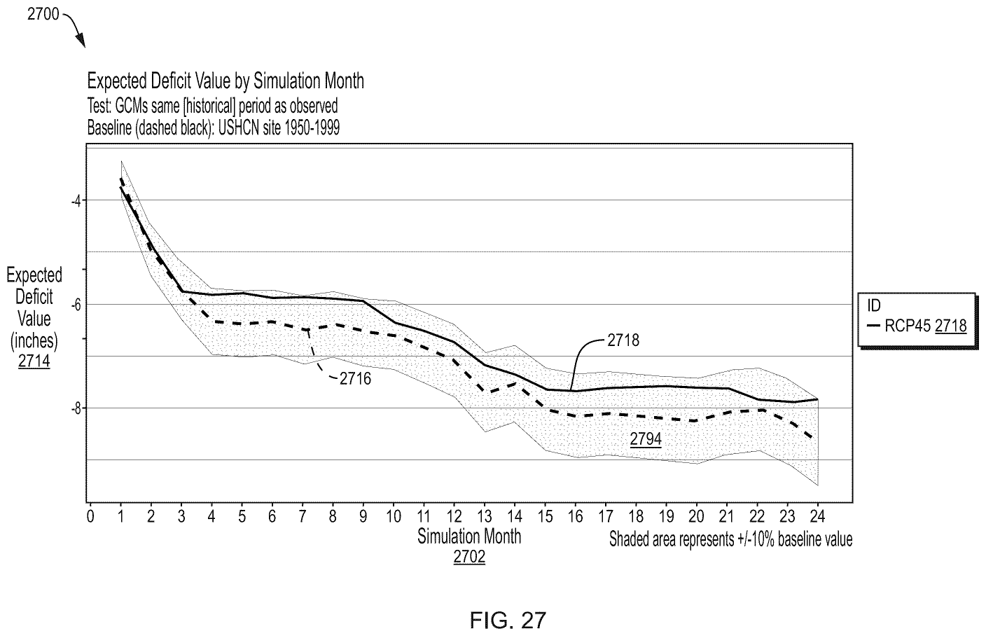

In an embodiment, once precipitation deficit statistics are calculated as described hereinabove, they can be used to assess whether climate model(s) can adequately simulate or project frequency, duration, and intensity of droughts when compared to a nearest rain gage. According to another embodiment, the visualizations discussed herein (or data on which the visualizations are based) can be analyzed qualitatively and/or quantitatively to determine if the example Methods 1A or 1B can be used at a site (i.e., a real-world geographic area). In an embodiment, these visualizations may include, for non-limiting examples:
a) Individual average monthly deficit and surplus comparisons for climate model(s) and rain gage(s) (e.g., FIGS. 19-21)
b) Cumulative precipitation deficits cumulative likelihood matrix (ces) (e.g., FIGS. 1A/1B and 25A/25B)
c) Weighted deficit/expected values of cumulative rainfall deficits (e.g., FIG. 27)
d) Cumulative surplus deficit plots by percentile for climate model(s) and rain gage(s) (e.g., FIGS. 22-24)
e) Percentile or frequency in a, e.g., ˜50-year period, for cumulative rainfall deficits of specific durations and deficit traces for climate model(s) and rain gage(s) (e.g., FIG. 3)

Confidence in the quantitative use of climate model(s) for future projections may be based on analyses of statistical hindcast comparisons to a rain gage or stochastic historical data, as well as percent differences between a gage and climate model(s) in any given month. For example, average rainfall values for any given month over a time period (such as all the Aprils in the period) can be calculated for historical data and GCM hindcast data, and if these values are consistently biased in one direction, or highly variable (for example, 50% higher values in some months and 50% lower in all the rest when comparing GCM and gage), this may suggest that GCMs are not suitable for direct use. This is a qualitative determination, based on patterns in calculated percentages.

If climate model(s) do not adequately match rain gage results, then the example Methods 2A and/or 2B may be applied as described hereinbelow.

### Example Application of Climate Model(s) in Projection Mode

In an embodiment, applying climate model(s) in projection mode may include the example steps described hereinabove for the example efficacy analysis(es). An example time period may be changed to, e.g., years 2050-2099, instead of years 1950-2004 that was used for the example efficacy analysis(es).

### Example Assessment and Application of Results for Future Predictions of Cumulative Rainfall Deficit, Frequency, Intensity, and Duration

In an embodiment, example results described hereinabove, whether from the example Methods 1A/B or Methods 2A/B, can be used for a wide variety of applications in water supply planning. Because these results offer future projections of rainfall deficit, frequency, duration, and intensity, the results can be used by hydrologic and statistical models directly, through formulation of future scenarios that reflect the projected statistics, or to characterize future droughts more quantitatively than is possible with existing approaches, such as by addressing predicted frequency, duration, and intensity of future rainfall deficits. The example results may be used with or without detailed water supply simulation models (reservoir models, aquifer models, streamflow models, etc.), such as in the following ways, for non-limiting examples:
a) Embodiments enable a new technique for formulating future timeseries of rainfall that match projected long-term cumulative statistics, and which can be used in water supply models, especially when combined with long-term temperature projections. Embodiments are superior to the conventional approach of directly simulating climate model output with water resource or supply models—an approach that fails to assure simulation of appropriate duration and frequency of future droughts.
b) Embodiments enable water managers and planners to understand long-term trends in climate-induced dry conditions both more quantitatively and without using simulation models. For instance, embodiments can predict a likelihood of increased or decreased risk of specific combinations of drought intensity, duration, and frequency. This is important because each individual supply system (reservoirs, aquifers, rivers, etc.) may be vulnerable to very unique combinations of these three factors, and it is not enough to only consider intensity, as is the existing practice in many states across the U.S.

### Example Methods 2A and 2B: Climate Model-Informed DCF(s) Applied to Rain Gage Data

In an embodiment, the example Methods 2A and 2B can be used either to corroborate and augment results from the example Methods 1A and 1B or in scenarios where climate model(s) in the example Methods 1A and 1B do not adequately reproduce historical deficit statistics.

According to another embodiment, both the example Methods 2A and 2B may use DCFs to develop projections, with the example Method 2A using rain gage data for a baseline, and the example Method 2B using rain gage data to develop stochastically generated baseline datasets.

### Example DCF Calculations

In an embodiment, DCF(s) may include a percent change between a baseline period and a projection period. The DCF(s) may represent expected changes in monthly rainfall amounts due to climate change. According to another embodiment, two example methods may be used to calculate DCF(s) as follows:
a) Example Modified Hybrid-Delta Method: In an embodiment, the existing Hybrid-Delta approach may be modified to eliminate known instabilities for the largest and smallest monthly rainfall amounts. It is noted that this example method may not require that baseline and projection periods be of equal length. According to another embodiment, this example modified technique may include the following steps, for non-limiting examples:
   i. Sort climate model monthly rainfall totals from smallest to largest for a selected projection period for climate model(s), e.g., each of 32 GCMs, using only months with rainfall.
   ii. Use data between, e.g., the 10^{th} and 90^{th} percentiles, to eliminate instabilities at the largest and smallest set of monthly rainfall values.
   iii. Calculate DCFs for each integer percentile for each climate model by dividing a projected rainfall value by a baseline value for each percentile for the data between, e.g., the 10^{th} and 90^{th} percentiles.
   iv. Estimate, e.g., the 1st through 10^{th} and 90^{th} through 100^{th} percentiles, using a linear regression curve for the 10^{th} to 90^{th} percentiles and extrapolating backwards and forwards. This may be done for each climate model.
   v. Sort baseline rain gage data or stochastically generated baseline gage data from smallest to largest.
   vi. Apply DCFs, e.g., integer DCFs, to the baseline gage data or stochastically generated baseline gage data for the corresponding integer percentiles.
   vii. Interpolate between integer DCFs to apply to each value between integer values.
b) Example Ranking DCF Method: In an embodiment, this technique may be used with the example Methods 2A and/or 2B. It is noted that this example method may use baseline and projection periods of equal length. According to another embodiment, this example technique may include the following steps, for non-limiting examples:
   i. Sort climate model monthly rainfall totals from smallest to largest for a baseline period for climate model(s), e.g., each of 32 GCMs, using all months, i.e., with and without rainfall.
   ii. Sort the climate model monthly rainfall totals from smallest to largest for a selected projection period for the climate model(s), e.g., all the 32 GCMs, using all months, i.e., with and without rainfall.
   iii. Sort baseline gage data or stochastically generated baseline gage data from smallest to largest.
   iv. Apply, e.g., all, the ranked DCFs to the ranked baseline gage data or stochastically generated baseline gage data on a one-to-one basis for the corresponding rank for, e.g., each of the 32 GCMs.
   v. If there is a zero monthly rainfall in the climate model baseline, a default DCF of 1 (one) may be used.
   vi. If there is a zero monthly rainfall in the climate model projection period, the DCF may be calculated to be 0 (zero) and may not be adjusted.

### Example Stochastic Technique

In an embodiment, a principle of an example stochastic approach may be that recorded rain gage data may represent only one sequence of plausible historical events, and that randomly sampling years or months into new sequences of actual observed rainfall measurements may expand an envelope of plausible historical conditions. In this context, an example method may not be validated against history, but may rather form a broader basis of historical data for the example Methods 1B and/or 2B. Also in this context, the example Methods 2A and/or 2B may be bolstered by a stochastic dataset to which DCF(s) are applied, which may extend the utility of DCF(s) from adjusting the magnitude of precipitation deficits to adjusting the frequency and duration of deficits.

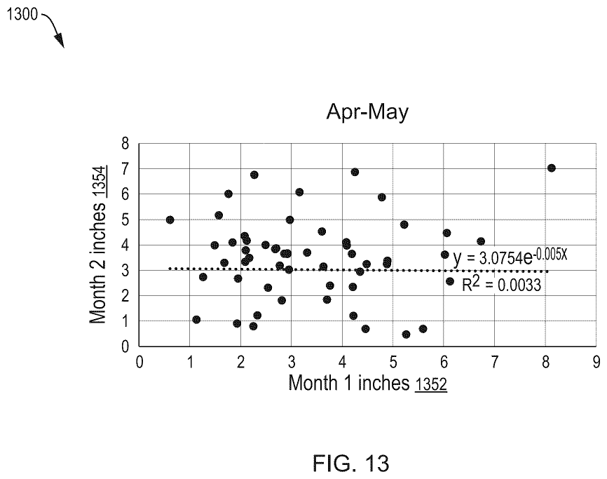

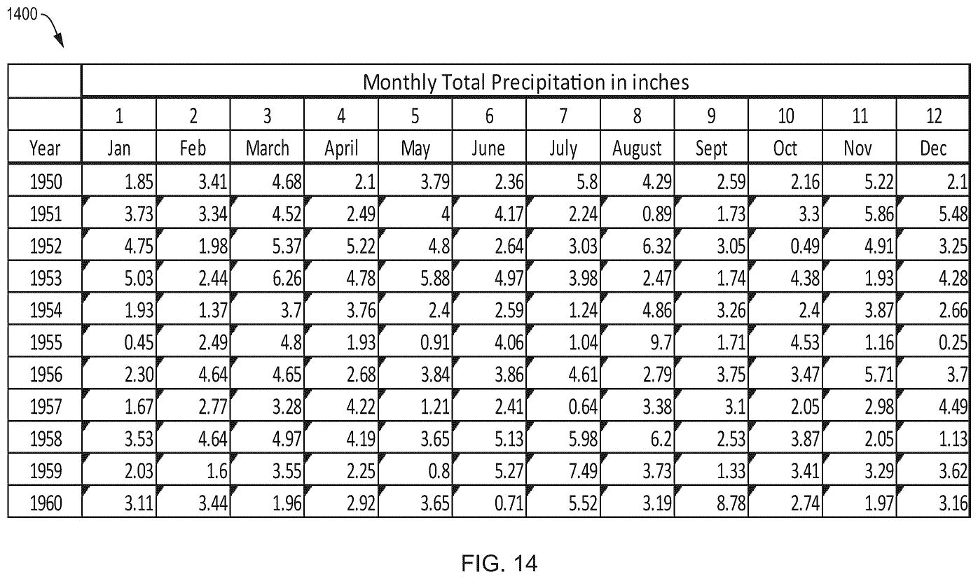

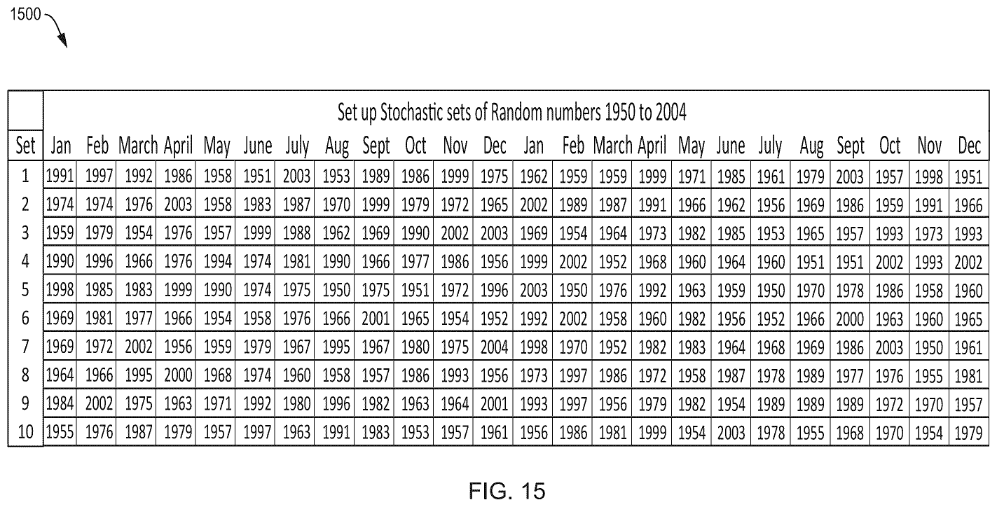

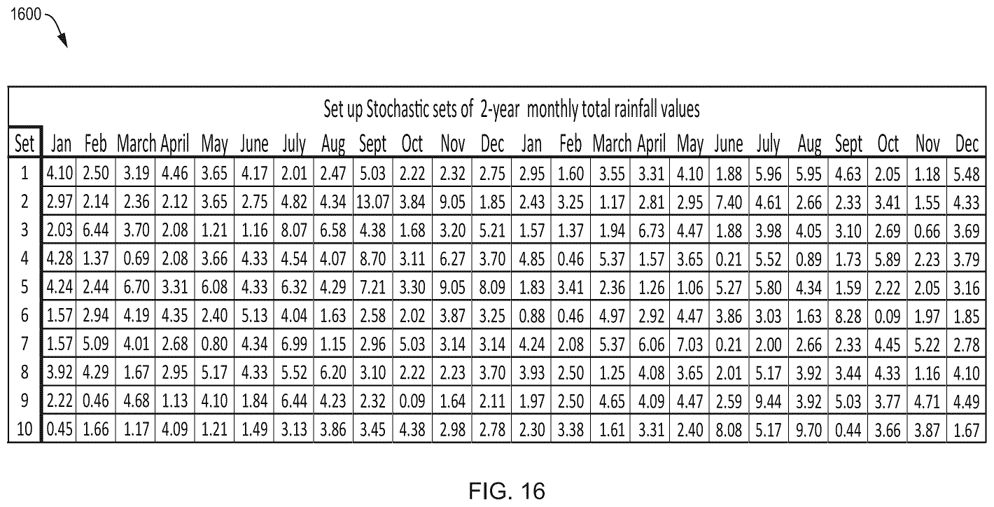

In an embodiment, the stochastic technique for rain gage data for the Methods 1B and/or 2B may include the following steps, for non-limiting examples:
a) Download gage precipitation data (e.g., hourly, daily) and sum it to monthly totals for a period of record.
b) Calculate the 12 average monthly values from the gage data using the selected period of record.
c) Determine independence of monthly precipitation records: Graph each month against each subsequent month's rainfall in a scatter plot and identify or analyze for correlation. Independence may form a basis for subsequent random sampling and sequencing. FIG. 13 illustrates an example of this technique according to an embodiment. As shown in FIG. 13, example graph 1300 plots inches of rainfall 1352 in Month 1, i.e., April, against inches of rainfall 1354 in Month 2, i.e., May. FIG. 13 depicts an example of independence analysis prior to random sampling of historical monthly rainfall values, with a very low coefficient of determination (R²) of 0.0033, which indicates that the month-to-month rainfall deficit values are independent of each other; the y value of 3.0754e^{-0.005x} is the best fit correlation equation, and its R² value is the percentage measuring the fit.
d) Create a table of monthly gage values for precipitation for each year of the selected period of record. This may be, for example, rows for years 1950-2004 and columns for each month, January-December, where each cell contains the gage precipitation total for each month for each year. An example of the first few months is shown in FIG. 14, which is an example table 1400 of monthly gage data according to an embodiment.
e) Create a table of a set of randomly generated synthetic years, e.g., 500 rows with each row being a set of 24-60 monthly rainfall totals and showing January for Year 1 through December for Year 2 (up to, e.g., Year 5) as columns. Sampling for January, for example, may come from each value for January in a period of record. Each cell may create a randomly generated year within a selected time period, e.g., randomly generated years between 1950 and 2004. An example of ten years of randomly selected years is shown in FIG. 15, which is an example table 1500 of randomly sequenced months according to an embodiment.
f) Create a set of stochastically generated, e.g., two-year sequences (or longer or shorter), by matching each month's generated year to a gage value for that month and that year. An example of randomly generated 24-month rainfall sequences is shown in FIG. 16, which is an example table 1600 of randomly sequenced historical monthly rainfall data according to an embodiment.
g) Compare a match of average monthly rainfall values from a rain gage to average monthly totals from, e.g., 500 generated rows of precipitation. Also verify that the example stochastic technique produces a slightly wider range than the gage, e.g., maximum annual or monthly rainfall, and minimum annual or monthly rainfall, which may be expected because the technique is evaluating natural variability beyond a period used for the gage.

### Example Stochastically Generated Future Conditions: Example Methods 2A/2B

In an embodiment, projections can be made using gage data or randomly generated monthly sequences of historical rainfall data.

According to another embodiment, the example Method 2A may use historical record data from a rain gage as a baseline. The example Method 2B may create a broader envelope of baseline rainfall deficit frequencies, durations, and magnitudes than occurred historically as captured in actual baseline period data. According to yet another embodiment, in both methods (i.e., the Methods 2A and 2B), each monthly value of rainfall in a baseline source dataset may be adjusted up or down using one or both sets of DCFs developed using the example Modified Delta-Hybrid Method or example Ranking DCF Method as described herein.

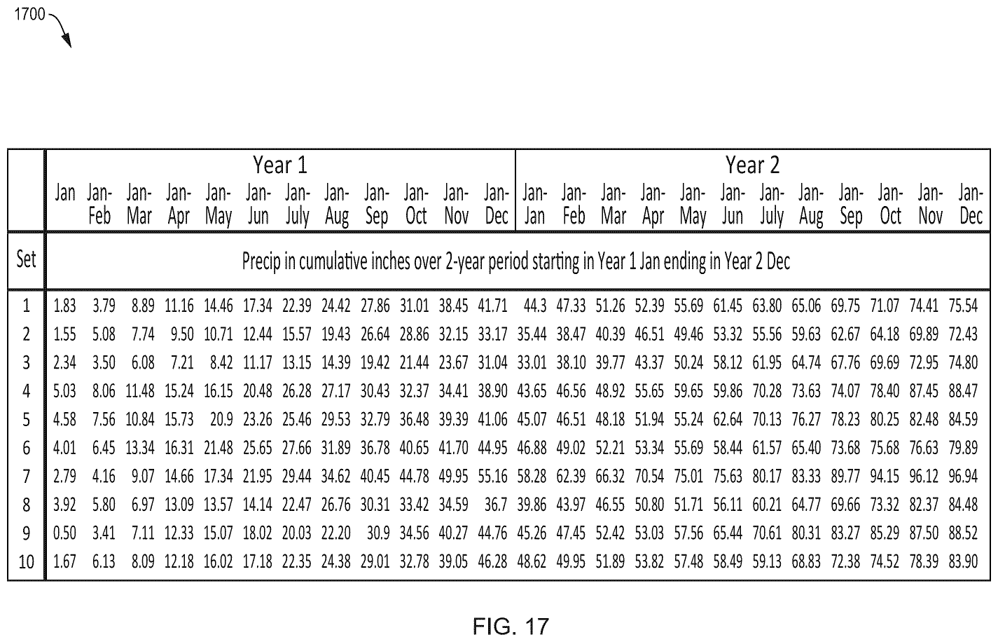

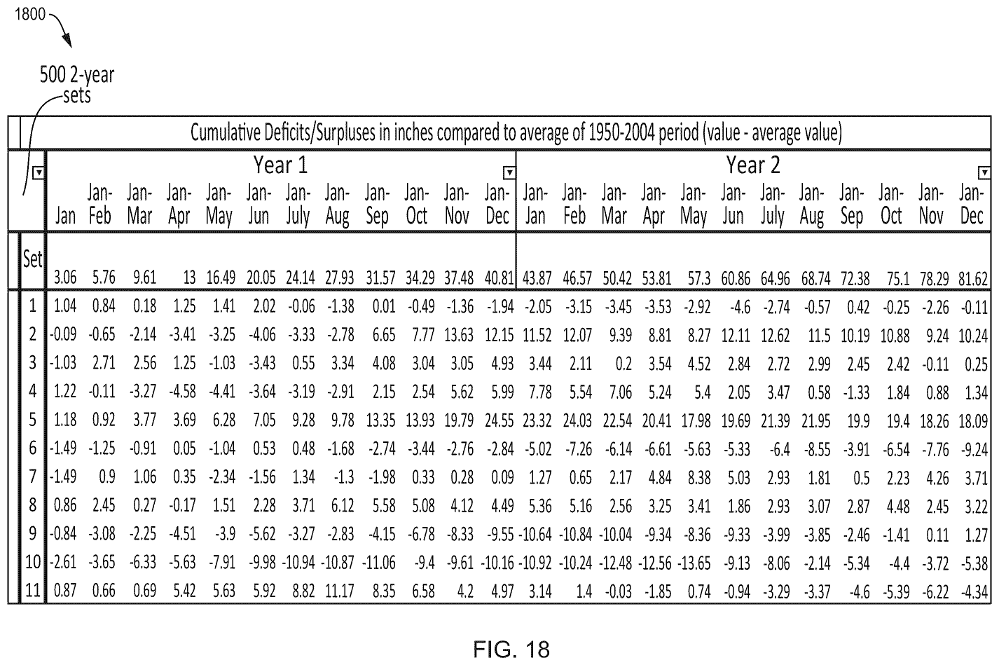

In an embodiment, steps to create projections may include, for non-limiting example:
a) Create a set of cumulative monthly precipitation values for an x-year period by summing all months prior to each cell for each of the projected sets. An example of ten rows for two-year sets is shown in FIG. 17, which is an example table 1700 of stochastically generated cumulative rainfall values according to an embodiment.
b) Create a set of cumulative deficits/surplus for each set from a matrix generated in example Step a) by subtracting cumulative values from the matrix in Step a) from monthly averages based on gage monthly averages. An illustration of this is shown in FIG. 18, which is an example table 1800 of stochastically cumulative rainfall deficits/surpluses according to an embodiment.
c) Create two frequency tables for inch-by-inch deficits/surpluses, one for frequencies between two values, and a second one for frequency of deficits/surpluses above a value. This may be done using the generated deficits/surpluses from example Step b) and counting a number of occurrences in each deficit category.
d) Create two likelihood tables by dividing frequency by a number of sets, e.g., 500, that were created.

In an embodiment, the remaining example steps may be the same as employed in the example Methods 1A and 1B, whereby statistical visualizations may be developed and used to compare projected future conditions to historical conditions, to determine how cumulative rainfall deficit frequency, duration, and intensity is likely to change—or not—in the future.

It should be noted that, in an embodiment, results from the example Method 1A and/or 1B can be compared to results from the example Method 2A and/or 2B at each location. If results are in close agreement, the methods may be considered corroborated—thereby significantly boosting confidence in future drought planning and projection with climate change considerations. If the results represent similar trends but different numerical statistics, they can be used together to create a future envelope, or range, of drought conditions for which to prepare. If the results are significantly divergent, this may indicate that uncertainty levels using climate model output directly are too high for quantitative planning or projection of coupled frequency, duration, and intensity of cumulative rainfall deficits for a given site/region. In this case, the example Methods 2A and/or 2B can be used.

### Example Advantages

Embodiments provide innovative new ways for climate model(s), e.g., GCM(s), to be analyzed with example efficacy tests for long-term drought-related performance, addressing all three defining traits of droughts together: duration, frequency, and intensity.

Further, embodiments provide quantitative guidance regarding if and how individual or ensembled climate model(s) can or should be used for drought planning and projection. Embodiments also avoid the risks of applying climate model(s) “blindly” based simply on how well the model(s) recreate monthly or annual rainfall statistics without regard to long-term sequencing and persistence of dry conditions. Moreover, embodiments provide a practical framework for evaluating climate model(s) for efficacy in long-term cumulative dry conditions.

If climate model hindcasts sufficiently match historical statistics for cumulative rainfall deficits, the climate model(s) can be used much more confidently with embodiments to project future rainfall trends that could be used to project long-term deficit durations, frequencies, and intensities, which is essential information for drought planning and projection.

Embodiments provide highly quantified evaluations that may also be transformed into visual interpretations by processing historic climate data and projections from available climate model(s) automatically.

Further, embodiments simplify drought prediction by simplifying it into a single quantitative indicator on a principle that a root cause of drought, and the most directly linked environmental variable to impacts of drought, is a lack of precipitation, e.g., rain or snow, over the long term. While other variables may affect water availability, droughts are fundamentally caused by a lack of precipitation. Conventional projection techniques attempt to include many environmental factors, but because of compounded uncertainty and subjectivity, results from existing techniques are often limited to qualitative guidance. Embodiments are entirely quantitative.

To counter an important shortcoming in the existing Hybrid-Delta ensemble method for future climate projections, specifically, that approach's inability to include coupled frequency and duration of rainfall deficits along with intensity, the example Method 2B of embodiments may include stochastic synthesis of plausible historical conditions to which climate model(s) can be applied through DCF(s) while predicting future frequency, duration, and intensity of cumulative rainfall deficit.

Converting results of climate model projections into an “expected value” of a future rainfall deficit, using an example efficacy analysis of embodiments, is itself an advancement in drought prediction. Traditional practice relies on qualitative indices, “what-if” analyses, and trends that fall short of quantifying an expected value of a cumulative rainfall deficit over any monthly duration up to five years. Unlike existing drought forecasting techniques that focus on trends that take too long to develop to be of use to small systems that are vulnerable to, e.g., three-month droughts, or which cannot faithfully predict dry conditions for over-year periods, embodiments offer significant value to water systems that are vulnerable to month-over-month drought conditions, as well as to those that are vulnerable to year-over-year drought conditions.

Drought prediction historically relies on one quantitative—and often unvalidated—technique, sometimes augmented by one or more qualitative techniques. By employing independent example quantitative methodologies for drought projection using the broadest array of available scientific information from climate model(s) and including validity analyses, embodiments provide increased confidence with which water managers and planners can prepare for future droughts.

Embodiments provide accurate drought predictions upon which real-world actions can be taken. For instance, water management decisions may be implemented based upon the results of embodiments. Moreover, embodiments may be used to automatically control water management systems, among other examples. As one example, a water utility may use results of an analysis provided by embodiments to help justify drought-resilience infrastructure improvements and work, such as advanced water purification, aquifer storage and recovery, reclaimed water, and regional water sharing. In another example real-world application results of an analysis provided by embodiments can be used to avoid regional drought-proofing investments. Results provided by embodiments can be leveraged to formulate policy and priorities—e.g., if droughts are projected to be less severe and frequent, capital funding for droughts can be deprioritized—and also quantitatively to help scale drought resilient infrastructure, such as new water sources, augmentation of water sources, enhanced conservation, etc., based on quantitative guidance on the plausible frequency, intensity, and duration of future droughts.

### Example Sequence of Efficacy Analyses

In an embodiment, the example efficacy analyses, e.g., all of the example efficacy analyses, described herein can be routinely performed for an individual project and/or real-world geographic area. According to another embodiment, when many sites are being considered at the same time, however, performing the example analyses in a particular sequence may be beneficial to a broader analysis by eliminating unsuitable climate model(s) for direct use and avoiding further analysis of additional visualizations.

In an embodiment, for non-limiting example, a sequence of the efficacy analyses may be as follows, with the first item acting as a threshold analysis:
a) Monthly Surplus/Deficit Analysis
b) Cumulative Precipitation Traces Analysis
c) Frequency-Severity Matrix Analysis
d) Cumulative Weighted Deficit Analysis
e) Cumulative Surplus/Deficit Analysis
f) Frequency Analysis

### Monthly Surplus/Deficit Analysis

In an embodiment, a first example analysis may be to evaluate monthly surplus/deficit. According to another embodiment, this example analysis can be used as an initial threshold evaluation to determine whether further analysis is needed or not. This example analysis may compare average rainfall over the period of interest, e.g., years 1950-1999, by month, for each climate model against rain gage averages.

In an embodiment, three example metrics may be calculated when evaluating climate model(s), e.g., all 32 GCMs.
a) Whether the climate model(s) exhibit a consistent bias, either too wet or too dry. If the bias is consistent but small, for example if average deviation over 12 months is less than 10%, this may indicate a high degree of matching. Additional example analysis(es) may also be performed.
b) Whether the climate model(s) exhibit a mix of wet and dry biases.
   i. If yes, but average deviations of the wet months are less than 10% and the average of the dry months is less than 10%, this may nonetheless indicate a high degree of matching. Additional example analysis(es) may also be performed.
   ii. If the biases average to 10%-20%, this may indicate a tentative match. Additional example analysis(es) may also be performed.
   iii. If the biases are greater than 20%, this may indicate a low degree of matching and direct use of the climate model output(s) may be unwarranted. Additional analysis may be unnecessary and the example Methods 2A and/or 2B may be applied.
c) Whether the climate model(s) exhibit a consistent wet bias or dry bias of over 10% for a season. If yes, then this may indicate a low degree of matching and direct use of the climate model output(s) may be unwarranted. Additional analysis may be unnecessary and the example Methods 2A and/or 2B may be applied.

### Example Statistics

In an embodiment, in addition to 10% lines in a visualization to highlight bars above and below a line, statistics are possible as well to make a determination more quantitative. According to another embodiment, each month may have a percent difference calculated in a plot. These values can be used for statistics as follows, for non-limiting examples:
a) Mean of absolute values of monthly percent differences: Calculate an absolute value of 12 differences and calculate a mean, which may ideally be below 10%. If the mean value is between 10% and 20%, then additional example analysis(es) may be performed.
b) Root mean square (RMS): An alternative analysis to mean of absolute values may be a RMS of the 12 differences. If the RMS is between 10% and 20%, then additional example analysis(es) may be performed.

### Example Visualizations

FIG. 19 is an example comparison 1900 of average percent rainfall differences 1974 for sample months 1972 among climate models 1976a-1976n according to an embodiment. The example 1900 may indicate a high degree of matching, with a mix of deficit and surplus, all of which may be less than 10%.

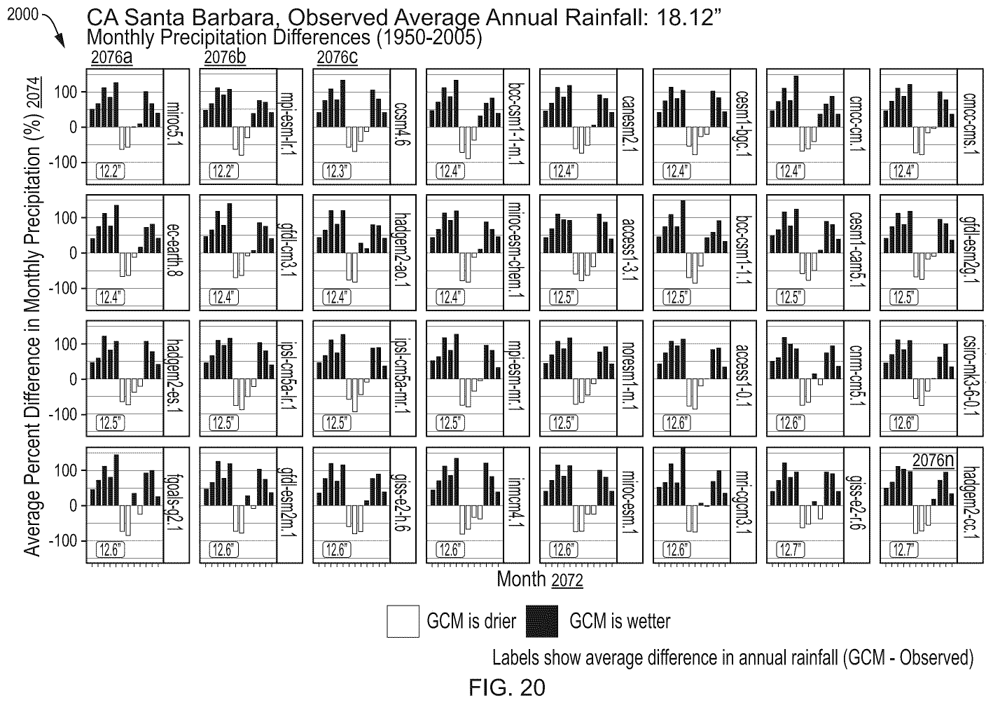

FIG. 20 is an example comparison 2000 of average percent rainfall differences 2074 for sample months 2072 among climate models 2076a-2076n according to an embodiment. The example 2000 may indicate a low degree of matching for both different seasonal biases and high percent deviations.

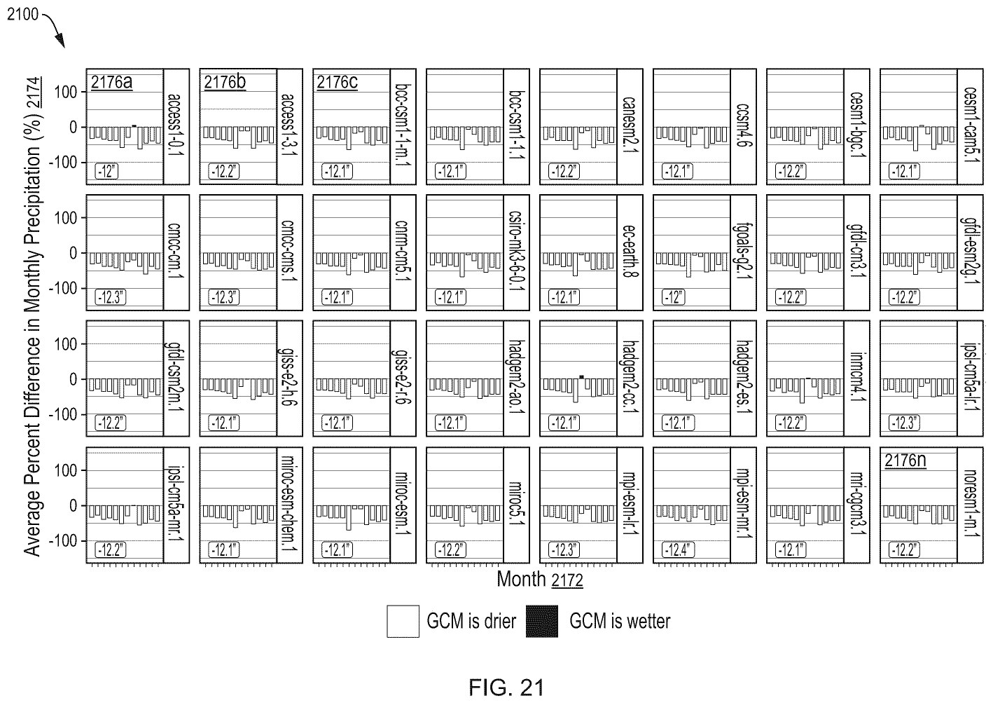

FIG. 21 is an example comparison 2100 of average percent rainfall differences 2174 for sample months 2172 among climate models 2176a-2176n according to an embodiment. The example 2100 may indicate a low degree of matching and show a consistent, high dry bias for an entire year.

### Example Cumulative Precipitation Traces Analysis

In an embodiment, cumulative precipitation traces may serve as an example analysis of climate model, e.g., GCM, accuracy. According to another embodiment, this example analysis may include generating visualizations. Further, in yet another embodiment, each line in an example visualization may indicate a percentile of all climate model(s) deficits less than values on the y-axis (e.g., 2224, described hereinbelow with respect to FIG. 22) for, e.g., a two-year or any length up to a five-year plot of cumulative precipitation surplus/deficit. In an embodiment, for a given visualization, e.g., FIG. 22 (described hereinbelow), a lefthand side plot, e.g., 2200a, may illustrate results for climate model hindcast(s) and a righthand side plot, e.g., 2200b, may depict rain gage data.

It should be noted that, in the case of visualizing, e.g., both RCP4.5 and RCP8.5, the historic periods may be the same, in which case the models may be referred to collectively as GCM historic values.

In an embodiment, this analysis may evaluate the below factors, for non-limiting examples:
a) Whether a spread of surplus and deficit is equal to or wider than a particular rain gage. The spread may be expected to be wider to some extent, but if more than, e.g., 10%-20%, then it may indicate a low degree of match.
b) Whether a spread and density of surpluses and deficits coincide with the rain gage.

### Example Visualizations

FIG. 22 illustrates example timeseries 2200a and 2200b for climate model(s) and a rain gage, respectively, of cumulative rainfall surplus and deficit 2224 for simulation months 2202 according to an embodiment. The example of FIG. 22 may depict a high degree of matching between the climate model(s) (timeseries 2200a) and the rain gage (timeseries 2200b). As shown in FIG. 22, climate model percentile lines 2278a-2278g for both surplus and deficits may approximately coincide with gage percentile lines 2278h-2278n. Both the climate model(s) and the gage may show a comparable spread of surplus and deficit, as well as a very similar range. The range of the climate model(s) (timeseries 2200a) may be larger to some extent than the range of the rain gage data (timeseries 2200b).

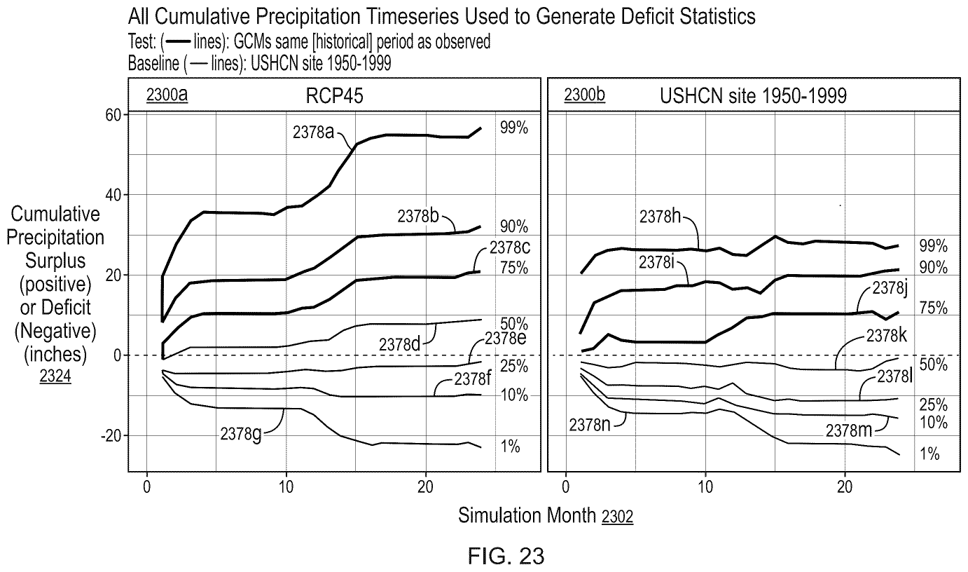

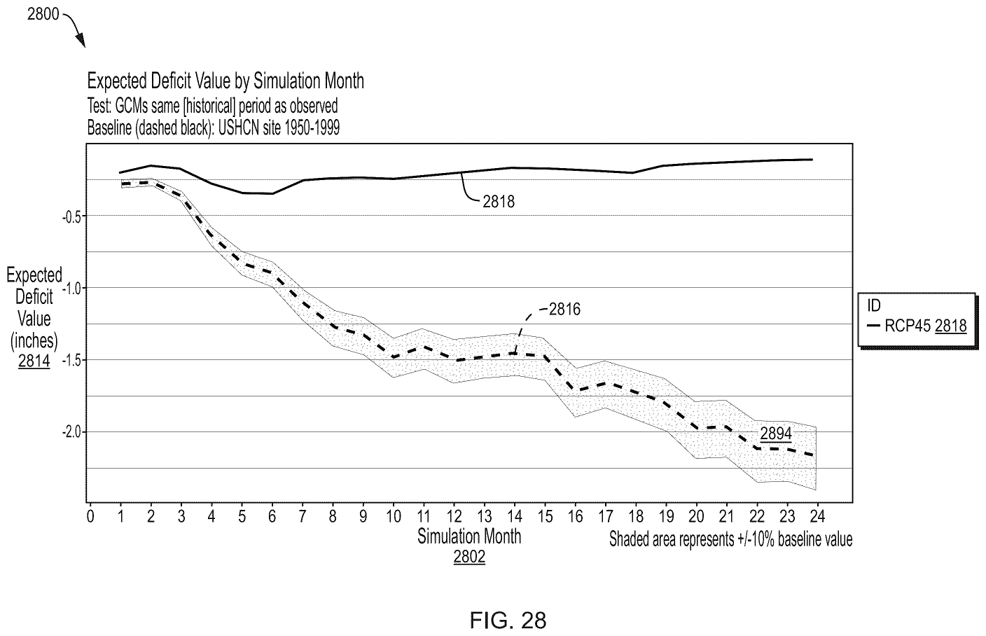

FIG. 23 illustrates example timeseries 2300a and 2300b for climate model(s) and a rain gage, respectively, of cumulative rainfall surplus and deficit 2324 for simulation months 2302 according to an embodiment. The example of FIG. 23 may depict a moderate or minimum degree of matching between the climate model(s) (timeseries 2300a) and the rain gage (timeseries 2300b). As shown in FIG. 23, a range of surpluses 2378a-2378d for the climate model(s) may exceed that of the rain gage in percentile lines 2378h-2378j. In contrast, deficits 2378e-2378g for the climate model(s) may coincide to some extent with deficits 2378k-2378n for the rain gage. FIG. 23 may show that the climate model(s) exhibit a wet bias, which may also be apparent from example monthly surplus/deficit visualizations (described in more detail hereinabove with respect to FIGS. 19-21), as well as from a substantially greater than 10% deviation in example visualizations (described in more detail hereinbelow with respect to FIGS. 27 and 28) for cumulative weighted deficits.

FIG. 24 illustrates example timeseries 2400a and 2400b for climate model(s) and a rain gage, respectively, of cumulative rainfall surplus and deficit 2424 for simulation months 2402 according to an embodiment. The example of FIG. 24 may depict a lack of matching between the climate model(s) and the rain gage. As shown in FIG. 24, the climate model(s) may exhibit a wet bias with deviations greater than 20% and a large shift upwards in both surplus 2478a-2478d and deficit 2478e-2478g percentile lines compared to corresponding percentile lines 2478h-2478j and 2478k-2478n for the rain gage.

### Example Frequency-Severity Matrix Analysis

In an embodiment, an example frequency-severity matrix analysis may generate visualization(s) that show frequency of each deficit (or surplus) bin by an amount of deficit. According to another embodiment, example visualization(s) may be color coded or shaded by frequency.

In an embodiment, this analysis may evaluate the below factors, for non-limiting examples:
a) Whether climate model(s), e.g., GCMs, have a comparable range to a rain gage. The climate model(s) may be expected to generate a wider range as compared to the rain gage.
b) Whether the climate model(s) and the rain gage have a comparable frequency pattern, e.g., whether for all months and deficit bins, ranges of frequency are similar, for instance, when represented by color coding/shading.

### Example Visualizations

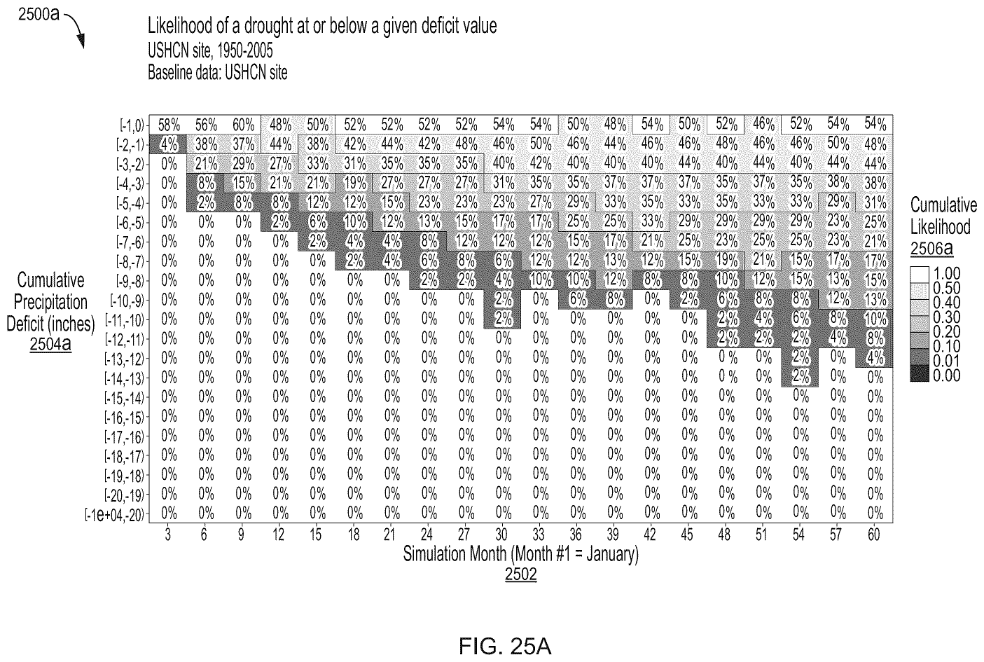

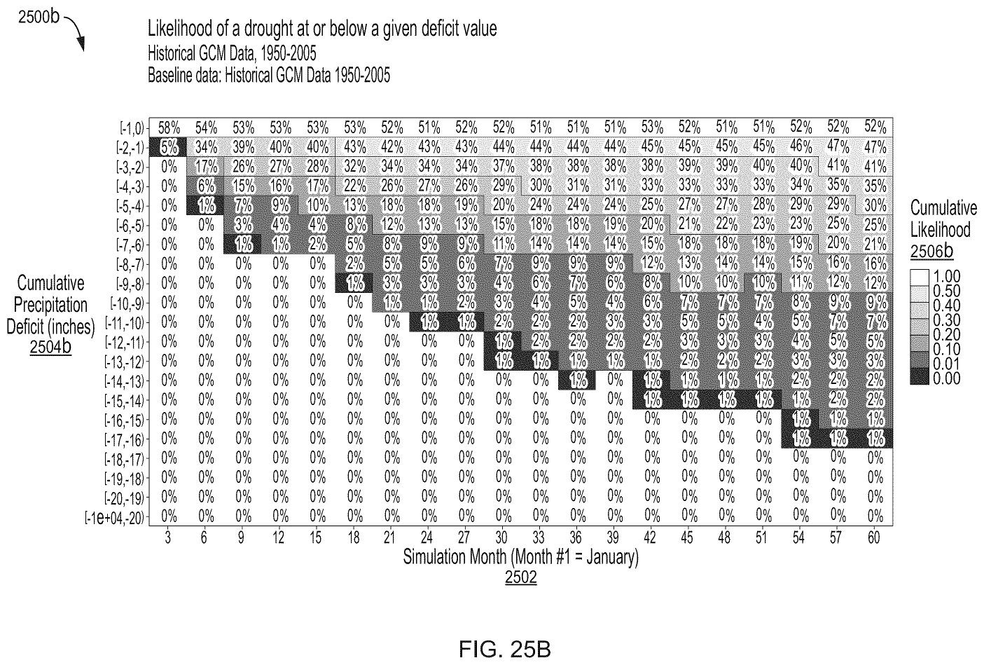

FIG. 25A is an example matrix 2500a showing rain gage cumulative precipitation deficits 2504a for simulation months 2502 at a location according to an embodiment. Portions of the matrix 2500a cells are shaded in accordance with key 2506a.

FIG. 25B is an example matrix 2500b showing climate model, e.g., GCM(s), hindcast cumulative precipitation deficits 2504b for simulation months 2502 at the location of FIG. 25A. Portions of the matrix 2500b cells are shaded in accordance with key 2506b.

The example matrices 2500a and 2500b may depict a high degree of matching between the climate model(s) and the rain gage. As shown in FIGS. 25A and 25B, a range of the climate model(s) in the matrix 2500b may be wider than a range of the rain gage in the matrix 2500a, e.g., more severe deficits may be shown in the matrix 2500b than in the matrix 2500a, but frequencies illustrated by the shading scheme 2506a/2506b in the matrices 2500a and 2500b may be similar.

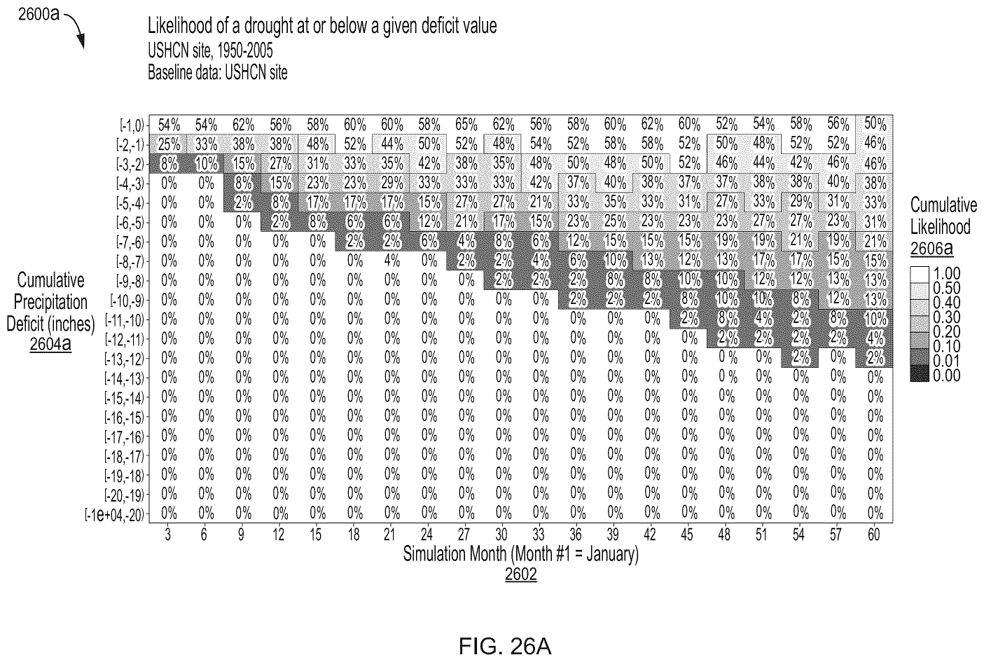

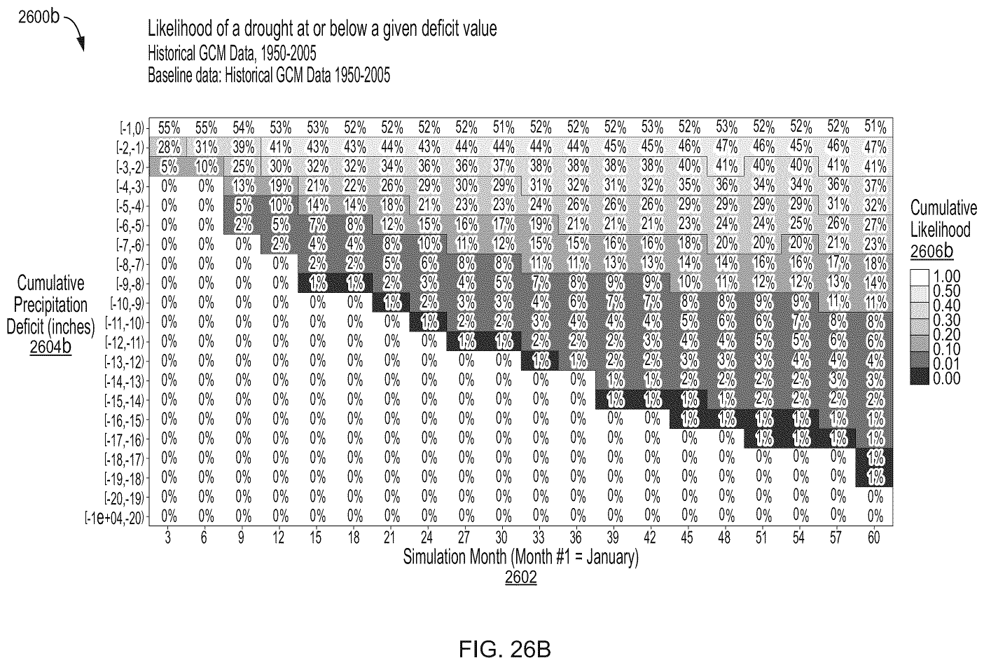

FIG. 26A is an example matrix 2600a showing rain gage cumulative precipitation deficits 2604a for simulation months 2602 at a location according to another embodiment. Portions of the matrix 2600a cells are shaded in accordance with key 2606a.

FIG. 26B is an example matrix 2600b showing climate model, e.g., GCM(s), hindcast cumulative precipitation deficits 2604b for simulation months 2602 at the location of FIG. 26A. Portions of the matrix 2600b cells are shaded in accordance with key 2606b.

The example matrices 2600a and 2600b may depict a low degree of matching between the climate model(s) and the rain gage. As shown in FIGS. 26A and 26B, a severity and frequency of deficits for the climate model(s) in the matrix 2600b may be much larger than for the rain gage in the matrix 2600a.

### Example Cumulative Weighted Deficit Analysis

In an embodiment, an example analysis is a weighted cumulative deficit analysis. According to another embodiment, this example analysis can also be performed for surpluses instead of deficits.

Further, in yet another embodiment, each month over a drought period being considered, e.g., below a 60-month drought, may have an expected value for cumulative surplus. The expected value for each month may be a sum of probabilities of each bin times a deficit bin value—where a “bin” may be equivalent to a cell in the matrices 2500a, 2500b, 2600a, and 2600b described herein in relation to FIGS. 25A, 25B, 26A, and 26B, respectively. The expected values may be added month by month over, e.g., a two to five year period under consideration, to develop a cumulative plot. This plot may include a 10% deviation shading. If climate model, e.g., an ensemble of climate models, values deviate more than 10%-20% for more than 10% of the months, i.e., 2 for a 24-month deficit, 6 for a 60-month deficit, the climate model(s) may have a low degree of matching.

### Example Statistics

In an embodiment, in addition to 10% lines in a visualization to highlight bars above and below a line, statistics may also be employed to make a determination of the adequacy of GCMs for projection more quantitative. According to another embodiment, for each month, a monthly deviation can be calculated by dividing an average difference of expected value of all climate model values, by month, by a gage value for each month. In yet another embodiment, either or both of the following statistics may be used, for non-limiting examples:
a) Mean of absolute values of monthly differences: Calculate an absolute value of monthly differences for each of the, e.g., 24 to 60 months under consideration, and calculate a mean, which may ideally be below 10% to 20%.
b) RMS: An alternative analysis may be an RMS of monthly differences for each of the, e.g., 24 to 60 months under consideration, which may ideally be below 10% to 20%.

### Example Visualizations

FIG. 27 is an example plot 2700 of expected rainfall deficit values 2714 for simulation months 2702 according to an embodiment. As shown in FIG. 27, climate model values 2718 are generally within deviation shading 2794 of baseline values 2716, thus indicating a high degree of matching.

FIG. 28 is an example plot 2800 of expected rainfall deficit values 2814 for simulation months 2802 according to another embodiment. As shown in FIG. 28, climate model values 2818 are outside deviation shading 2894 of baseline values 2816, thus indicating a low degree of matching.

### Example Cumulative Surplus/Deficit Analysis

In an embodiment, an example cumulative surplus/deficit analysis may be a further technique for assessing binned values, e.g., from the example matrices 2500a and 2500b (FIGS. 25A and 25B). According to another embodiment, either only deficits or surpluses may be used, or both may be used. These may be sorted from smallest to largest and plotted over a period, e.g., 24 to 60 months, against their percentiles.

### Example Visualization

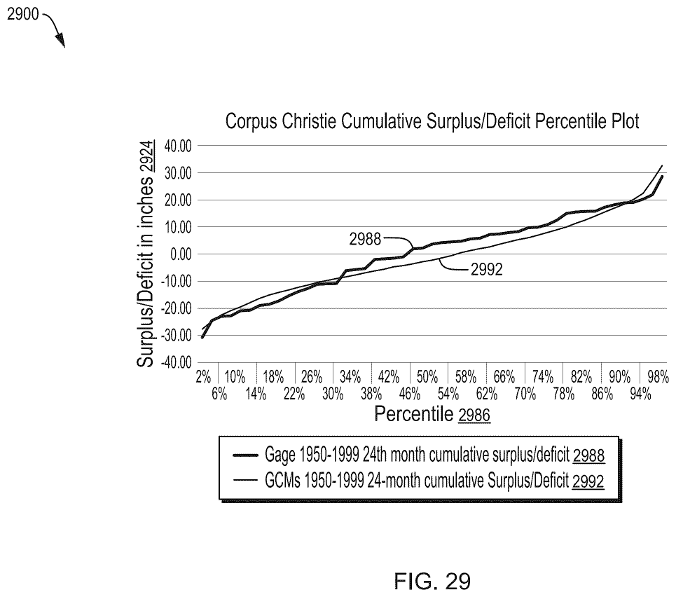

FIG. 29 is an example plot 2900 showing the percent 2986 of all deficits/surpluses 2924 smaller than each value. The example plot 2900 shows both deficits and surpluses in a single plot. FIG. 29 may illustrate a high degree of matching between rain gage 2988 and climate model 2992 values, with a moderate bias on the dry side for surpluses and a small bias on the wet side for deficits.

### Example Frequency Analysis

In an embodiment, an example frequency analysis may compare how frequently each bin value of surplus and deficit occurs in climate model(s) compared to a gage, e.g., in five-inch increments. According to another embodiment, given a sufficient number of gage points, the example frequency analysis may show any significant shifts or skews in the climate model output(s) compared to the gage baseline.

### Example Visualization

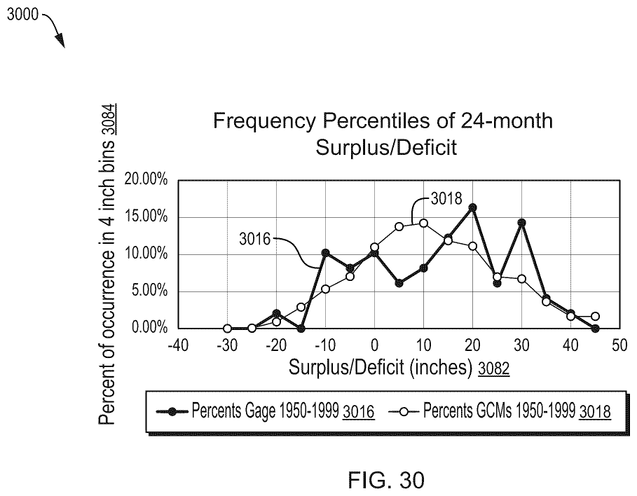

FIG. 30 is an example plot 3000 of rainfall surplus/deficit 3082 and frequency 3084 values for a rain gage 3016 and climate models 3018 according to an embodiment. As shown in FIG. 30, there is good agreement between the climate models 3018 and the rain gage 3016.

### Example Calculation of Drought Return Interval/AEP

Embodiments are also able to calculate drought return intervals and/or AEP. Traditionally, users may rely upon a drought of record for planning purposes, but they have no ability to assess a drought return interval because any given drought only occurs once. Embodiments provide innovative techniques to overcome this problem with existing approaches.

In an embodiment, droughts may be analyzed as specific events, for instance, cumulative rainfall in the 24^{th} month of a two-year drought. According to another embodiment, such events, i.e., month 24 deficits, can be stochastically generated, either for a baseline using rain gage data, or for rain gage data projections using DCF(s). By stochastically generating, e.g., thousands of 24^{th}-month—or any month—cumulative deficits, embodiments can produce a dataset to use for analyzing the most extreme events using a generalized extreme value approach to calculate a drought return interval or its inverse, AEP. This is another unique and very beneficial feature of embodiments.

FIG. 31 is an example plot 3100 of drought return interval years 3122 versus rainfall deficits 3132 for stochastically generated rain gage data 3194, climate model hindcast data 3192, and climate model forecast data 3196, according to an embodiment.

### Example Method Embodiment

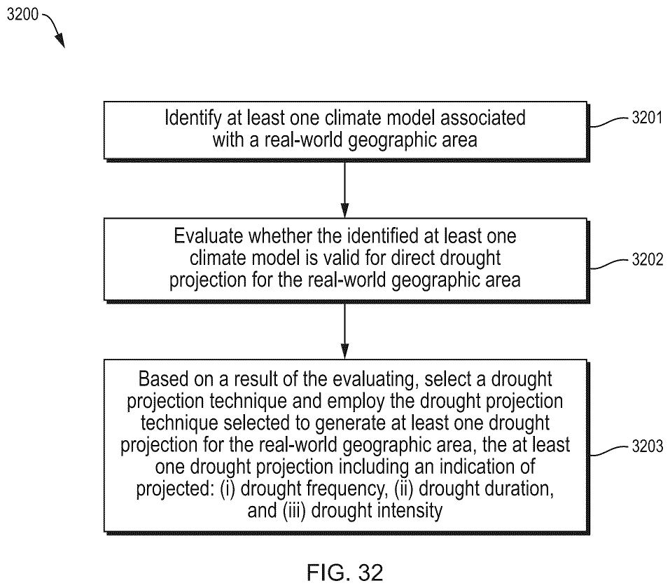

FIG. 32 is a flowchart of a method 3200 for drought projection for a real-world geographic area according to an example embodiment. The method 3200 is computer-implemented and may be implemented using any computing device, e.g., a processor, or combination of computing devices known to those of skill in the art.

The method 3200 begins at step 3201 by identifying at least one climate model associated with a real-world geographic area. Next, at step 3202, the method 3200 evaluates whether the identified at least one climate model is valid for direct drought projection for the real-world geographic area. Then, at step 3203, based on a result of the evaluating, a drought projection technique is selected and the drought projection technique selected is employed to generate at least one drought projection for the real-world geographic area. The at least one drought projection includes an indication of projected drought frequency, projected drought duration, and projected drought intensity, e.g., as shown in FIGS. 5 and 6 (described in detail hereinabove).

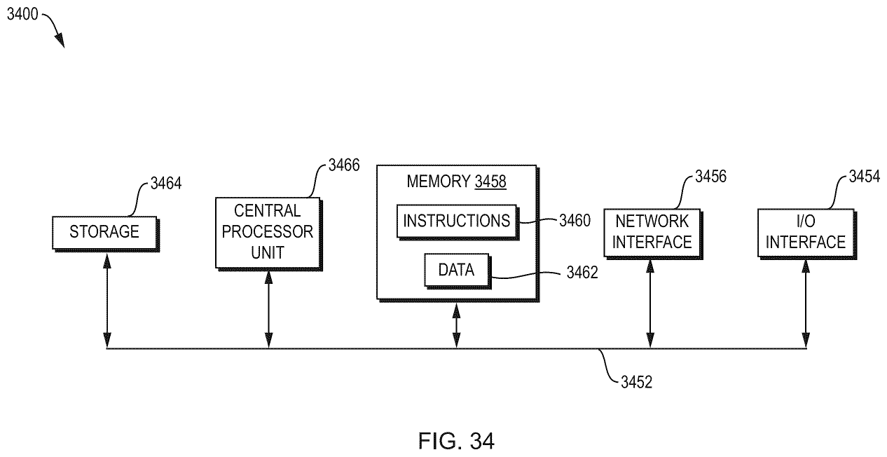

As noted, the method 3200 is computer-implemented and, as such, the functionality and effective operations, e.g., the identifying (3201), evaluating (3202), and selecting/employing (3203), are automatically implemented by one or more digital processors. The method 3200 can also be implemented using any computer device or combination of computing devices known in the art. Among other examples, the method 3200 can be implemented using a computer 3400 described hereinbelow in relation to FIG. 34.

In an example embodiment of the method 3200, the at least one climate model is identified at step 3201 by obtaining the at least one climate model from any suitable source known to those of skill in the art. According to an embodiment, the method 3200 may use, e.g., publicly available GCM CMIP5 projections. GCM CMIP5 projections can be downloaded from a range of different sources such as the USBR's data portal or NEX-GDDP. The data provided through the foregoing portals may come in netCDF format, which contains requested information such as number models and selected emission scenarios. An optional downscaling method selected for the data may be the LOCA technique that provides GCM output at a daily timestep and spatial resolution of 1/16°. According to another embodiment, for each location, daily precipitation volumes may be extracted from a netCDF file, e.g., through use of an R programming script, and may be processed for each climate model and emission scenario separately. In an embodiment, the at least one climate model may also include, e.g., CMIP6 dataset(s) and/or Regional Climate Model(s) (RCM(s)), the latter of which may be a result from dynamic downscaling.

In an example embodiment of the method 3200, the at least one climate model may be evaluated at step 3202 by leveraging any of the example efficacy analysis techniques described herein, including the techniques described hereinabove with respect to FIGS. 1A/1B and 2-4.

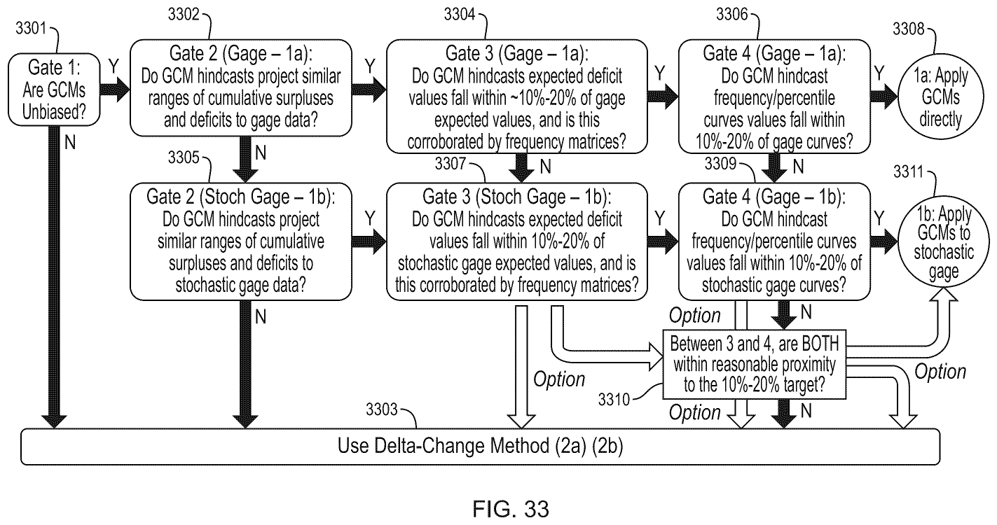

In an example embodiment of the method 3200, the drought projection technique selected and employed to generate the at least one drought projection at step 3203 may be any of the example Methods 1A, 1B, 2A, and 2B described hereinabove with respect to FIGS. 8-10. According to another example embodiment, the drought projection technique may be selected based on the decision process 3300 described hereinbelow in relation to FIG. 33.

According to an embodiment of the method 3200, the at least one climate model identified at step 3201 may include downscaled daily precipitation data from at least one of a GCM included in a CMIP model simulation, an RCP emission scenario simulation, and an ensemble of multiple climate models.

In an example embodiment of the method 3200, the evaluating 3202 may include: (1) using the identified at least one climate model to generate a rainfall hindcast for the real-world geographic area; (2) determining a difference between the generated rainfall hindcast and historical rainfall data for the real-world geographic area; and (3) based on the determined difference, determining a level of validity of the at least one climate model for direct drought projection for the real-world geographic area, wherein the determined level of validity is the result of the evaluating. According to one such embodiment, the generated rainfall hindcast may include at least one rainfall average for the real-world geographic area. The determining the difference may include determining a variance between the at least one rainfall average and the historical rainfall data and the variance may be the determined difference. In another such embodiment, the generated rainfall hindcast may include at least one cumulative rainfall deficit for the real-world geographic area. The determining the difference may include determining a variance between an expected value of the at least one cumulative rainfall deficit and the historical rainfall data. The variance may be the determined difference. According to yet another such embodiment, the generated rainfall hindcast may include at least one cumulative rainfall deficit for the real-world geographic area. The determining the difference may include determining a variance between at least one of: (i) a frequency, intensity and duration of the at least one cumulative rainfall deficit; and (ii) the historical rainfall data. The variance may be the determined difference. In yet another embodiment, the generated rainfall hindcast may include at least one cumulative rainfall deficit for the real-world geographic area. The determining the difference may include determining a variance between at least one percentile of the at least one cumulative rainfall deficit and the historical rainfall data. The variance may be the determined difference. According to another such embodiment, the generated rainfall hindcast may be a stochastic rainfall hindcast. The historical rainfall data may be stochastically-generated historical rainfall data.

According to another example embodiment of the method 3200, based on the result of the evaluating, selecting the drought projection technique and employing the drought projection technique selected at step 3203 to generate the at least one drought projection for the real-world geographic area may include, responsive to the result of the evaluating indicating that the identified at least one climate model is valid for direct drought projection: (1) selecting a direct drought projection technique that utilizes the identified at least one climate model; and (2) generating the at least one drought projection using the selected direct drought projection technique.

In an example embodiment of the method 3200, based on the result of the evaluating, selecting the drought projection technique and employing the drought projection technique selected at step 3203 to generate the at least one drought projection for the real-world geographic area may include, responsive to the result of the evaluating indicating that the identified at least one climate model is valid for direct drought projection: (1) selecting a direct stochastic drought projection technique that utilizes the identified at least one climate model; and (2) stochastically generating the at least one drought projection using the selected direct stochastic drought projection technique.

According to another example embodiment of the method 3200, based on the result of the evaluating, selecting the drought projection technique and employing the drought projection technique selected at step 3203 to generate the at least one drought projection for the real-world geographic area may include, responsive to the result of the evaluating indicating that the identified at least one climate model is not valid for direct drought projection: (1) selecting a delta change factor (DCF)-based drought projection technique that utilizes the identified at least one climate model; (2) processing historical rainfall data for the real-world geographic area using the selected DCF-based drought projection technique to generate adjusted rainfall data for the real-world geographic area; and (3) using the adjusted rainfall data, stochastically generating the at least one drought projection. In one such embodiment, the selected DCF-based drought projection technique may be a modified Hybrid-Delta technique. Processing the historical rainfall data using the selected DCF-based drought projection technique to generate the adjusted rainfall data may include: (1) processing the historical rainfall data using the identified at least one climate model to generate a plurality of projected rainfall values; (2) identifying a subset of the plurality of projected rainfall values, the subset having projected rainfall values greater than zero; (3) calculating at least one integer DCF corresponding to a respective at least one integer percentile of the projected rainfall values of the subset; and (4) applying the calculated at least one integer DCF to a corresponding at least one integer percentile of historical rainfall values of the historical rainfall data. Applying the calculated at least one integer DCF may produce the adjusted rainfall data. According to another such embodiment, the selected DCF-based drought projection technique may be a ranking DCF technique. Processing the historical rainfall data using the selected DCF-based drought projection technique to generate the adjusted rainfall data may include: (1) processing the historical rainfall data using the identified at least one climate model to generate a plurality of projected rainfall values; (2) identifying a first subset of the plurality of projected rainfall values, the first subset corresponding to a time period associated with the at least one drought projection; (3) identifying a second subset of the plurality of projected rainfall values, the second subset corresponding to a time period associated with the historical rainfall data; and (4) applying at least one DCF to a corresponding at least one historical rainfall value of the historical rainfall data. A rank of a given historical rainfall value of the historical rainfall data may correspond to at least one of a respective rank of a projected rainfall value of the first subset and a respective rank of a projected rainfall value of the second subset. Applying the at least one DCF may produce the adjusted rainfall data. Further, in yet another such embodiment, the selected DCF-based drought projection technique may be a Hybrid-Delta technique.

In an example embodiment of the method 3200, based on the result of the evaluating, selecting the drought projection technique and employing the drought projection technique selected at step 3203 to generate the at least one drought projection for the real-world geographic area may include, responsive to the result of the evaluating indicating that the identified at least one climate model is not valid for direct drought projection: (1) selecting a stochastic DCF-based drought projection technique that utilizes the identified at least one climate model; (2) processing historical rainfall data for the real-world geographic area to generate stochastic historical rainfall data for the real-world geographic area; (3) processing the stochastic historical rainfall data using the selected stochastic DCF-based drought projection technique to generate stochastic adjusted rainfall data for the real-world geographic area; and (4) using the stochastic adjusted rainfall data, stochastically generating the at least one drought projection.

According to another example embodiment of the method 3200, the evaluating 3202 may include, using the identified at least one climate model, generating a rainfall hindcast for the real-world geographic area and using the generated rainfall hindcast to calculate at least one of cumulative precipitation, a cumulative precipitation deficit, and at least one cumulative precipitation deficit statistic. In one such embodiment, using the generated rainfall hindcast to calculate the at least one cumulative precipitation deficit statistic may include: (1) based on the generated rainfall hindcast, defining a set of a precipitation timeseries sequences; (2) calculating respective cumulative precipitation deficits corresponding to the precipitation timeseries sequences; and (3) based on a size of the defined set and the respective cumulative precipitation deficits calculated, calculating at least one cumulative precipitation deficit frequency (or likelihood). The calculated at least one cumulative precipitation deficit frequency may be the at least one cumulative precipitation deficit statistic. According to another such embodiment, the defining the set of precipitation timeseries may include performing at least one of: (i) based on a duration value, filtering the generated rainfall hindcast and (ii) stochastically sampling the generated rainfall hindcast. A result of the performing may be the defined set of the precipitation timeseries sequences. In one such embodiment, the generated rainfall hindcast may be a stochastic rainfall hindcast for the real-world geographic area. The evaluating 3202 may further include, based on the cumulative precipitation deficit, calculating at least one of a drought return interval and a drought AEP.

In an example embodiment of the method 3200, the method may further include, based on the generated at least one drought projection, simulating at least one scenario of a real-world water system using at least one of a water resource model, a groundwater model, a water supply model, and a hydrologic model. According to one such embodiment, the real-world water system may include at least one of a reservoir, an aquifer, a river, a stream, a lake, a pond, a wetland, a marsh, a bog, a swamp, an estuary, a spring, a bay, a lagoon, a delta, and a canal.

### Example Drought Projection Technique Selection Process

FIG. 33 is a flowchart of an example decision process 3300 for drought projection technique selection according to an example embodiment. As shown in FIG. 33, the process 3300 includes the following example steps:
a) Step 3301: Evaluate climate models, e.g., GCM(s), for bias. If the climate model(s) are determined to be unbiased the method 3300 proceeds to step 3302. Else, if the climate model(s) are determined to be biased, then the method 3300 proceeds to step 3303.
b) Step 3302: Determine whether climate model hindcast(s) project ranges of cumulative surpluses and deficits similar to rain gage data. If yes, then proceed to step 3304. Else, if no, then proceed to step 3305.
c) Step 3303: Utilize a DCF-based technique informed by the climate model(s), i.e., the example Method 2A (non-stochastic) or 2B (stochastic), for drought projection.
d) Step 3304: Determine whether climate model hindcast expected deficit value(s) are within approximately 10%-20% of rain gage expected values, and whether such a finding is corroborated by frequency matrix (ces). If yes, then proceed to step 3306. Else, if no, then proceed to step 3307.
e) Step 3305: Determine whether the climate model hindcast(s) project ranges of cumulative surpluses and deficits similar to stochastic rain gage data. If yes, then proceed to step 3307. Else, if no, then proceed to step 3303.
f) Step 3306: Determine whether climate model frequency/percentile curve(s)/value(s) are within approximately 10%-20% of rain gage curve(s)/value(s). If yes, then proceed to step 3308. Else, if no, then proceed to step 3309.
g) Step 3307: Determine whether the climate model hindcast expected deficit value(s) are within approximately 10%-20% of stochastic rain gage expected values, and whether such a finding is corroborated by frequency matrix (ces). If yes, then proceed to step 3309. Else, if no, then optionally proceed to either step 3303 or step 3310.
h) Step 3308: Utilize the climate model(s) directly for drought projection, i.e., the example Method 1A.
i) Step 3309: Determine whether climate model frequency/percentile curve(s)/value(s) are within approximately 10%-20% of stochastic rain gage curve(s)/value(s). If yes, then proceed to step 3311. Else, if no, then optionally proceed to either step 3303 or step 3310.
j) Optional Step 3310: If the answer is no at (i) both steps 3304 and 3307 or (ii) both steps 3306 and 3309 then, the method 3300 may optionally proceed to step 3310. Step 3310 considers whether the analysis at steps (i) 3304 and 3307 or (ii) 3306 and 3309, was within reasonably proximity to the 10% to 20% target is yes, then, the method 3300 may optionally proceed to step 3311, if no, the method 3300 moves to step 3303. Further, it is noted that if the method 3300 moves to step 3311 from step 3310 then, the method 3300 may also proceed to step 3303, i.e., move to both steps 3311 and 3303 from step 3310.
k) Step 3311: Utilize the climate model(s) directly for drought projection in a stochastic manner, i.e., the example Method 1B.

### Computer Support

FIG. 34 is a block diagram of an example embodiment of an internal structure of a computer 3400 in which various embodiments of the present disclosure may be implemented. The computer 3400 contains a system bus 3452, where a bus is a set of hardware lines used for data transfer among the components of a computer or digital processing system. The system bus 3452 is essentially a shared conduit that connects different elements of a computer system (e.g., processor, disk storage, memory, input/output (I/O) ports, network ports, etc.) that enables the transfer of information between the elements. Coupled to the system bus 3452 is an I/O device interface 3454 for connecting various input and output devices (e.g., keyboard, mouse, displays, printers, speakers, etc.) to the computer 3400. A network interface 3456 allows the computer 3400 to connect to various other devices attached to a network (e.g., global computer network, wide area network (WAN), local area network (LAN), etc.). As shown in FIG. 34, memory 3458 may provide volatile or non-volatile storage for computer software instructions 3460 and data 3462 that may be used to implement embodiments of the present disclosure, where the volatile and non-volatile memories are examples of non-transitory media. Disk storage 3464 may also or alternately provide non-volatile storage for the computer software instructions 3460 and the data 3462 that may be used to implement embodiments of the present disclosure. A central processor unit (CPU) 3466 is also coupled to the system bus 3452 and provides for the execution of computer instructions.

As used herein, the terms “model” and “framework” may refer to any hardware, software, firmware, electronic control component, processing logic, and/or processor device, individually or in any combination, including without limitation: (1) an application specific integrated circuit (ASIC); (2) a field-programmable gate array (FPGA); (3) an electronic circuit; (4) a processor and memory that executes one or more software or firmware programs; and/or (5) other suitable components that provide the described functionality.

Example embodiments disclosed herein may be configured using a computer program product; for example, controls may be programmed in software for implementing example embodiments. Further example embodiments may include a non-transitory computer-readable medium that contains instructions that may be executed by a processor, and, when loaded and executed, cause the processor to complete methods described herein. It should be understood that elements of the block and flow diagrams may be implemented in software or hardware, such as via one or more arrangements of circuitry of FIG. 34, or equivalents thereof, firmware, a combination thereof, or other similar implementation determined in the future.

In addition, the elements of the block and flow diagrams described herein may be combined or divided in any manner in software, hardware, or firmware. If implemented in software, the software may be written in any language that can support the example embodiments disclosed herein. The software may be stored in any form of computer readable medium, such as random-access memory (RAM), read-only memory (ROM), compact disk read-only memory (CD-ROM), and so forth. In operation, a general purpose or application-specific processor or processing core loads and executes software in a manner well understood in the art. It should be understood further that the block and flow diagrams may include more or fewer elements, be arranged or oriented differently, or be represented differently. It should be understood that implementation may dictate the block, flow, and/or network diagrams and the number of block and flow diagrams illustrating the execution of embodiments disclosed herein.

The teachings of all patents, published applications, and references cited herein are incorporated by reference in their entirety.

While example embodiments have been particularly shown and described, it will be understood by those skilled in the art that various changes in form and details may be made therein without departing from the scope of the embodiments encompassed by the appended claims.

What is claimed is:

1. A computer-implemented method for drought projection for a real-world geographic area, the computer-implemented method comprising:
identifying at least one climate model associated with the real-world geographic area;
evaluating whether the identified at least one climate model is valid for direct drought projection for the real-world geographic area; and
based on a result of the evaluating, selecting a drought projection technique and employing the drought projection technique selected to generate at least one drought projection for the real-world geographic area, the at least one drought projection including an indication of projected: (i) drought frequency, (ii) drought duration, and (iii) drought intensity.

2. The computer-implemented method of claim 1, wherein the evaluating includes:
using the identified at least one climate model, generating a rainfall hindcast for the real-world geographic area;
determining a difference between the generated rainfall hindcast and historical rainfall data for the real-world geographic area; and
based on the determined difference, determining a level of validity of the at least one climate model for direct drought projection for the real-world geographic area, wherein the determined level of validity is the result of the evaluating.

3. The computer-implemented method of claim 2, wherein the generated rainfall hindcast includes at least one rainfall average for the real-world geographic area, and wherein the determining the difference includes:
determining a variance between the at least one rainfall average and the historical rainfall gage data, wherein the variance is the determined difference.

4. The computer-implemented method of claim 2, wherein the generated rainfall hindcast includes at least one cumulative rainfall deficit for the real-world geographic area, and wherein the determining the difference includes:
determining a variance between an expected value of the at least one cumulative rainfall deficit and the historical rainfall data, wherein the variance is the determined difference.

5. The computer-implemented method of claim 2, wherein the generated rainfall hindcast includes at least one cumulative rainfall deficit for the real-world geographic area, and wherein the determining the difference includes:
determining a variance between (i) at least one of a frequency and an intensity of the at least one cumulative rainfall deficit and (ii) the historical rainfall data, wherein the variance is the determined difference.

6. The computer-implemented method of claim 2, wherein the generated rainfall hindcast includes at least one cumulative rainfall deficit for the real-world geographic area, and wherein the determining the difference includes:
determining a variance between at least one percentile of the at least one cumulative rainfall deficit and the historical rainfall data, wherein the variance is the determined difference.

7. The computer-implemented method of claim 2, wherein the generated rainfall hindcast is a stochastic rainfall hindcast, and wherein the historical rainfall data is stochastically-generated historical rainfall data.

8. The computer-implemented method of claim 1, wherein, based on the result of the evaluating, selecting the drought projection technique and employing the drought projection technique selected to generate the at least one drought projection for the real-world geographic area includes:
responsive to the result of the evaluating indicating that the identified at least one climate model is valid for direct drought projection:
selecting a direct drought projection technique that utilizes the identified at least one climate model; and
generating the at least one drought projection using the selected direct drought projection technique.

9. The computer-implemented method of claim 1, wherein, based on the result of the evaluating, selecting the drought projection technique and employing the drought projection technique selected to generate the at least one drought projection for the real-world geographic area includes:
responsive to the result of the evaluating indicating that the identified at least one climate model is valid for direct drought projection:
selecting a direct stochastic drought projection technique that utilizes the identified at least one climate model; and
stochastically generating the at least one drought projection using the selected direct stochastic drought projection technique.

10. The computer-implemented method of claim 1, wherein, based on the result of the evaluating, selecting the drought projection technique and employing the drought projection technique selected to generate the at least one drought projection for the real-world geographic area includes:
responsive to the result of the evaluating indicating that the identified at least one climate model is not valid for direct drought projection:
selecting a delta change factor (DCF)-based drought projection technique that utilizes the identified at least one climate model;
processing historical rainfall data for the real-world geographic area using the selected DCF-based drought projection technique to generate adjusted rainfall data for the real-world geographic area; and
using the adjusted rainfall data, stochastically generating the at least one drought projection.

11. The computer-implemented method of claim 10, wherein the selected DCF-based drought projection technique is a modified Hybrid-Delta technique, and wherein processing the historical rainfall data using the selected DCF-based drought projection technique to generate the adjusted rainfall data includes:
processing the historical rainfall data using the identified at least one climate model to generate a plurality of projected rainfall values;
identifying a subset of the plurality of projected rainfall values, the subset having projected rainfall values greater than zero (0);
calculating at least one integer DCF corresponding to a respective at least one integer percentile of the projected rainfall values of the subset; and
applying the calculated at least one integer DCF to a corresponding at least one integer percentile of historical rainfall values of the historical rainfall data, wherein applying the calculated at least one integer DCF produces the adjusted rainfall data.

12. The computer-implemented method of claim 10, wherein the selected DCF-based drought projection technique is a ranking DCF technique, and wherein processing the historical rainfall data using the selected DCF-based drought projection technique to generate the adjusted rainfall data includes:
processing the historical rainfall data using the identified at least one climate model to generate a plurality of projected rainfall values;
identifying a first subset of the plurality of projected rainfall values, the first subset corresponding to a time period associated with the at least one drought projection;
identifying a second subset of the plurality of projected rainfall values, the second subset corresponding to a time period associated with the historical rainfall data; and
applying at least one DCF to a corresponding at least one historical rainfall value of the historical rainfall data, wherein a rank of a given historical rainfall value of the historical rainfall data corresponds to at least one of: (i) a respective rank of a projected rainfall value of the first subset and (ii) a respective rank of a projected rainfall value of the second subset, and wherein applying the at least one DCF produces the adjusted rainfall data.

13. The computer-implemented method of claim 1, wherein, based on the result of the evaluating, selecting the drought projection technique and employing the drought projection technique selected to generate the at least one drought projection for the real-world geographic area includes:
responsive to the result of the evaluating indicating that the identified at least one climate model is not valid for direct drought projection:
selecting a stochastic delta change factor (DCF)-based drought projection technique that utilizes the identified at least one climate model;
processing historical rainfall data for the real-world geographic area to generate stochastic historical rainfall data for the real-world geographic area;
processing the stochastic historical rainfall data using the selected stochastic DCF-based drought projection technique to generate stochastic adjusted rainfall data for the real-world geographic area; and
using the stochastic adjusted rainfall data, stochastically generating the at least one drought projection.

14. The computer-implemented method of claim 1, wherein the evaluating includes:
using the identified at least one climate model, generating a rainfall hindcast for the real-world geographic area; and
using the generated rainfall hindcast to calculate at least one of: (i) cumulative precipitation, (ii) a cumulative precipitation deficit, and (iii) at least one cumulative precipitation deficit statistic.

15. The computer-implemented method of claim 14, wherein using the generated rainfall hindcast to calculate the at least one cumulative precipitation deficit statistic includes:
based on the generated rainfall hindcast, defining a set of a precipitation timeseries sequences;
calculating respective cumulative precipitation deficits corresponding to the precipitation timeseries sequences; and
based on (i) a size of the defined set and (ii) the respective cumulative precipitation deficits calculated, calculating at least one cumulative precipitation deficit frequency, wherein the calculated at least one cumulative precipitation deficit frequency is the at least one cumulative precipitation deficit statistic.

16. The computer-implemented method of claim 15, wherein the defining includes:
performing at least one of: (i) based on a duration value, filtering the generated rainfall hindcast and (ii) stochastically sampling the generated rainfall hindcast;
wherein a result of the performing is the defined set of the precipitation timeseries sequences.

17. The computer-implemented method of claim 14, wherein the generated rainfall hindcast is a stochastic rainfall hindcast for the real-world geographic area, and wherein the evaluating further includes:
based on the cumulative precipitation deficit, calculating at least one of: (i) a drought return interval and (ii) a drought annual exceedance probability (AEP).

18. The computer-implemented method of claim 1, further comprising:
based on the generated at least one drought projection, simulating at least one scenario of a real-world water system using at least one of: (i) a water resource model, (ii) a groundwater model, (iii) a water supply model, and (iv) a hydrologic model.

19. A computer-based system for drought projection for a real-world geographic area, the computer-based system comprising:
at least one processor; and
a memory with computer code instructions stored thereon, the at least one processor and the memory, with the computer code instructions, being configured to cause the computer-based system to:
identify at least one climate model associated with the real-world geographic area;
evaluate whether the identified at least one climate model is valid for direct drought projection for the real-world geographic area; and
based on a result of the evaluating, select a drought projection technique and employ the drought projection technique selected to generate at least one drought projection for the real-world geographic area, the at least one drought projection including an indication of projected: (i) drought frequency, (ii) drought duration, and (iii) drought intensity.

20. A computer program product for drought projection for a real-world geographic area, the computer program product comprising a non-transitory computer-readable medium with computer code instructions stored thereon, the computer code instructions being configured, when executed by at least one processor, to cause the at least one processor to:
identify at least one climate model associated with the real-world geographic area;
evaluate whether the identified at least one climate model is valid for direct drought projection for the real-world geographic area; and
based on a result of the evaluating, select a drought projection technique and employ the drought projection technique selected to generate at least one drought projection for the real-world geographic area, the at least one drought projection including an indication of projected: (i) drought frequency, (ii) drought duration, and (iii) drought intensity.
